(19) United States
(12) Patent Application Publication
(10) Pub. No.: US 2026/0185871 A1
(43) Pub. Date: Jul. 2, 2026

(54) Quantum Coherent Receiver

(71) Applicant: California Institute of Technology, Pasadena, CA (US)

(72) Inventors: Baris Volkan GURSES, Pasadena, CA (US); Seyed Ali HAJIMIRI, La Canada Flintridge, CA (US)

(73) Assignee: California Institute of Technology, Pasadena, CA (US)

(21) Appl. No.: 18/819,803

(22) Filed: Aug. 29, 2024

Related U.S. Application Data
(60) Provisional application No. 63/535,209, filed on Aug. 29, 2023.

(51) Int. Cl. G01J 1/44; G02F 1/01; G02F 1/21; G02F 1/225; G06F 11/07; H03F 3/45

(52) U.S. Cl. CPC G01J 1/44; G02F 1/0147; G02F 1/212; G02F 1/225; G06F 11/0721; G06F 11/0793; H03F 3/45475; G01J 2001/442; G01J 2001/446

(57) ABSTRACT

A receiver for a quantum signal comprising a mixer for mixing or interfering a local oscillator signal and the quantum signal to form interference signals; and a pair of balanced photodetectors for outputting a difference signal in response thereto. The receiver further comprises electronics for amplifying and determining a quadrature component of the quantum signal from the difference signal with quantum noise limited precision. Methods and systems for using the receiver are further disclosed.

### CROSS-REFERENCE TO RELATED APPLICATIONS

This application claims the benefit under 35 U.S.C. Section 119 (e) of the following co-pending and commonly-assigned U.S. Provisional Patent Application Ser. No. 63/535,209 filed Aug. 29, 2023 entitled “Quantum Coherent Receiver” (CIT 9059) by Baris Volkan Gurses and Seyed Ali Hajimiri, which application is incorporated by reference herein.

This application is related to U.S. patent application Ser. No. 18/629,732 field Apr. 8, 2024, entitled “QUANTUM PHASED ARRAYS” which application claims the benefit under 35 U.S.C. Section 119 (e) of U.S. Provisional Application No. 63/457,727 filed Apr. 6, 2023, by B. Volkan Gurses, Samantha I. Davis, Maria Spiropulu, Ali Hajimiri, entitled “QUANTUM PHASED ARRAYS,” (CIT-8990-P), which applications are incorporated by reference herein.

### BACKGROUND OF THE INVENTION

### 1. Field of the Invention

The present disclosure relates to coherent receivers and methods for making and using the same.

### 2. Description of the Related Art

Coherent light detection is ubiquitous in many systems for communications, sensing, and computing. An arbitrary optical state can be described by its phase space with two axes representing its two orthogonal quadratures, and the variances of these two quadratures at best saturate the Heisenberg uncertainty principle (ΔxΔp≥ℏ/2). Extracting an optical state's quadrature information in the phase space or in constellation diagrams allows coherent optical systems to have two degrees of freedom (i.e. amplitude and phase) for encoding and decoding optical information in a symbol. While this bound cannot be violated, the “shape” of the symbol can be manipulated to increase information capacity with quantum coherent systems, which the current classical communications has yet to leverage.

Classical optical states, such as coherent light, have a constant variance with respect to any quadrature phase and, therefore, cannot go below the Heisenberg-limited bound. Non-classical states, such as squeezed coherent light, can surpass this bound and allow quantum coherent optical systems to manipulate the single photon statistics of light [1]. This can allow these systems to encode and decode information in additional degrees of freedom, more than the two degrees of freedom (amplitude and phase) that classical coherent optical systems can control. This opens up an effectively unlimited controllable number of degrees of freedom in constellation diagrams of current communication systems. What is needed are detection systems that can measure these degrees of freedom in quantum coherent communications applications and quantum sensing applications. The present invention satisfies this need.

### SUMMARY OF THE INVENTION

A receiver for a quantum signal, comprising a mixer for mixing or interfering a local oscillator signal and a quantum signal to form interference signals; and a pair of photodetectors that can be balanced for outputting a difference signal in response the interference signals. The receiver typically further comprises an electronic circuit for amplifying the difference signals and determining a quadrature component of the quantum signal from the difference signals with shot noise limited precision/sensitivity or sub-shot noise limited precision/sensitivity. The receiver further comprises control circuits for controlling common mode rejection ratio, Shot Noise Clearance, and Pₖₙₑₑ for different operation bandwidths.

Also disclosed are communication systems and sensor system (and methods of using the same) that utilize the receiver for detection of the quantum signals.

### BRIEF DESCRIPTION OF THE DRAWINGS

The patent or application file contains at least one drawing executed in color. Copies of this patent or patent application publication with color drawing(s) will be provided by the Office upon request and payment of the necessary fee

Referring now to the drawings in which like reference numbers represent corresponding parts throughout:

FIG. 1a: Coherent, squeezed, and an arbitrary state to be used in quantum coherent communications. Replacing coherent states with arbitrary quantum optical states introduce additional controllable degrees of freedom, enabling noise reduction and enhancement of information capacity.

FIG. 1b. Example of encoding information in the variances of the two quadratures in squeezed states.

FIG. 2: A diagram of a quantum coherent receiver (QRX) with the corresponding operators for the annihilation-creation operator formalism and the port number for the scattering matrix formalism.

FIG. 3: Design guide for the QRX at a single sideband frequency.

FIG. 4: The frequency spectrum and RF characterization of the QRX with the corresponding definition for the noise equivalent power.

FIG. 5: Design guide for the QRX optoelectronic bandwidth.

FIG. 6: An example tunable QRX with auto-CMRR correction using LO power as the error signal. The output current is converted to a voltage error signal in the feedback resistor of the TIA. The error signal is sent through an integrator to extract the DC component and amplify the voltage to be fed back to the phase shifters. Phase shifters tune the MZI's coupling ratio until CMRR is minimized.

FIG. 7: An example high-level diagram and summary of the tunable QRX with auto-CMRR correction.

FIG. 8a. Micrograph of the integrated receiver with an area of 0.00200 mm².

FIG. 8b. Noise floor integrated over 3 MHz of bandwidth with varying LO powers showing 26.0 dB SNC and 34.6 μWPₖₙₑₑ.

FIG. 8c. Pump power sweep of the SPDC source showing μ=0.055 mW^{1/2}.

FIG. 9a. Setup with the silicon photonic receiver for squeezed light measurements, showing Erbium doped fiber amplifier (EDFA), periodically poled lithium niobate (PPLN), beamsplitter (BS) and arbitrary waveform generator (AWG).

FIG. 9b. Oscillations between quadratures of the squeezed vacuum. Red crosses signify the squeezed quadrature.

FIG. 9c. Demonstration of phase locking to the squeezed quadrature showing the noise floor (top) and modulator voltage (bottom).

FIG. 10a. Diagram of the packaged photonic-electronic chip with the characterization setup.

FIG. 10b. Measured normalized gain and common-mode rejection ratio response of the QRX.

FIG. 10c. Measured noise floor spectra of the QRX at different LO photocurrents. d) Measured total and electronic noise subtracted noise floors integrated over the bandwidth of the QRX with a shot noise fit of slope 1.007±0.015.

FIG. 11a. Setup with the integrated photonic-electronic coherent receiver for squeezed light measurements.

FIG. 11b. Oscillations between quadratures of the squeezed vacuum measured at 1.17 GHz. Red crosses signify the squeezed quadrature.

FIG. 11c. Shot noise clearance response of the QRX with maximum LO photocurrent.

d) Quadrature noise normalized to the shot noise level of vacuum for squeezed and anti-squeezed quadratures.

FIG. 12a. Simplified circuit diagram of the QRX with CMRR auto-correction. A low-frequency error signal is extracted by probing the DC current through the TIA feedback resistor. The resulting voltage is sent to an integrator op-amp isolated from the TIA. The output voltage from the integrator is sent to the push-pull MZI to automatically correct the DC offset current from the balanced PD. The polarity of the feedback circuit ensures the MZI is pushed toward 50:50 coupling when LO power is higher than signal power.

FIG. 12b. IV characteristic of the push-pull TOPS, comprising resistive heaters with series diodes. Either one of the heaters is turned on depending on the polarity of the driving voltage by turning on/off the series diodes. Linear regression fits are applied to the data points when the diodes are on to extract 1.02 kΩ and 1.03 kΩ resistance for heater 1 and heater 2, respectively. The forward voltages for the diodes in heater 1 and heater 2 are 0.921 V and 0.911 V, respectively.

FIG. 12c. MZI response of the push-pull MZI constructed from the measured half-wave power of 18 mW and the measured IV characteristic.

FIG. 13a. The packaged die photo and the simplified schematic of the high-BW QRX.

FIG. 13b. SNC curve of the high-BW QRX showing 14.0 dB SNC and 521 μWPₖₙₑₑ along with the measured electronic noise floor and the theoretical thermal noise floor. A linear regression fit is applied to the measured data to show the QRX is signal shot noise limited with its noise power increasing linearly with LO power, showing a near-unity gradient of 1.009±0.016.

FIG. 13c. Measured noise spectra for varying LO powers showing raw data (semi-transparent lines) and processed data with a moving average filter (solid lines).

FIG. 13d. Measured optoelectronic gain of the high-BW QRX showing a 3-dB bandwidth of 2.57 GHz.

FIG. 13e. Measured SNC spectrum of the high-BW QRX showing a shot-noise-limited bandwidth of 3.50 GHz.

FIG. 14a. SNC curve of the high-SNC QRX showing 30.3 dB SNC and 12.5 μAₖₙₑₑ along with the measured electronic noise floor and the theoretical thermal noise floor. A linear regression fit is applied to the measured data to show the QRX is signal shot noise limited with its noise power increasing linearly with LO power, showing a near-unity gradient of 1.004±0.006.

FIG. 14b. Measured noise spectra for varying LO powers showing raw data (semi-transparent lines) and processed data with a moving average filter (solid lines).

FIG. 14c. Measured SNC spectrum of the high-SNC QRX showing a shot-noise-limited bandwidth of 381 MHz.

FIG. 15a. Measured averaged spectra when the MZI is set to balanced and unbalanced configurations with the same LO power showing a peak amplitude difference of 86.8 dB limited by the dynamic range of the ESA.

FIG. 15b Measured averaged spectra when the MZI is set to balanced and unbalanced configurations with 18.2 dB higher LO power for the unbalanced configuration measurement. The peak amplitude difference is 59.8 dB, corresponding to a CMRR of 90.2 dB.

FIG. 16: Photo of the QRX array chip on top of a penny (left). Photos of the packaged photonic-electronic system comprising the chip wirebonded to an interposer interfaced with an RF motherboard (right).

FIG. 17a. Measured CMRR improvement spectra of all 32 channels setting the lower bound on their CMRRs.

FIG. 17b. Histogram of the maximum CMRR improvements showing a median of 76.8 dB, a minimum of 52.4 dB, and a maximum of 104.2 dB.

FIG. 18a. Measured SNC spectra of all 32 channels showing shot-noise-limited operation across all QRXs.

FIG. 18b. Histogram of the SNCs showing a median of 25.3 dB, a minimum of 27.7 dB, and a maximum of 26.6 dB.

FIG. 19. Communication system comprising a receiver according to one or more embodiments.

FIG. 20. Sensor system comprising a receiver according to one or more embodiments.

FIG. 21 illustrates a system diagram for the quantum computing embodiment, comprising source array comprising nonlinear medium, optical interferometer for matrix multiplication, LO input receiver array, RF/microwave circuit for matrix multiplication, and analog to digital converter, digital electronics, and classical computer.

FIG. 22 illustrates the equivalent quantum circuit of the system in FIG. 21.

FIG. 23 illustrates a method of making a receiver.

FIG. 24 illustrates a method of operating a receiver.

FIG. 25 illustrates a classical computer system that can be used with the receiver.

FIG. 26 illustrates a network classical computer system that can be used with the receiver.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

### Technical Description

### 1. Introduction

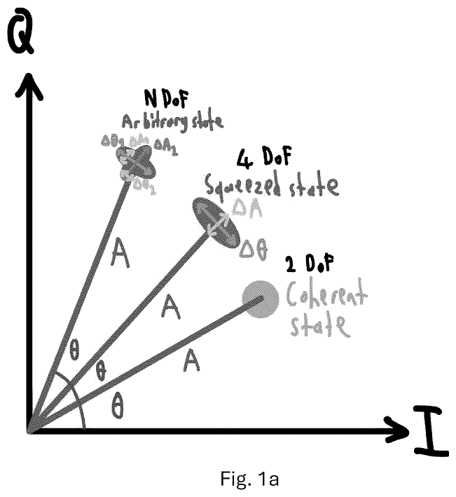

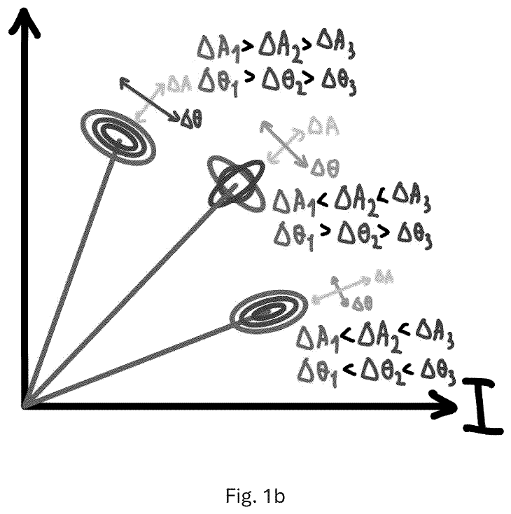

As discussed above, quantum coherent communications leverage the current coherent communications infrastructure to enhance its data capacity in addition to enabling applications for the quantum industry in quantum computing, sensing, and communications. A selection of some quantum optical states for use in quantum coherent communications is shown in FIG. 1.

Having these additional degrees of freedom in quantum coherent communications can allow quantum coherent systems to reduce the quantum-limited noise floor of classical coherent systems below the shot noise floor for their channel capacity to surpass the standard Shannon limit. This quantum-enhanced information capacity is then bounded by the Holevo limit [2]. In addition to reducing the noise floor, information can also be encoded in the quadrature variance to leverage the manipulation of photon statistics and correlations in an arbitrary quantum optical state in addition to the classical coherent optical encoding in amplitude A and phase θ as seen in FIG. 1, wherein variance in A and θ is denoted ΔA and Δθ respectively.

This additional functionality over information storage and transfer in quantum coherent systems will have an impact on any information technology with applications in communications, sensing and computing.

### 2. Quantum Coherent Receiver

As the optoelectronic building block of quantum coherent communications and quantum optoelectronic systems, we introduce a novel quantum-limited coherent optical receiver capable of decoding quantum information encoded in quantum optical states for applications in communications, sensing, and computing. This quantum coherent receiver (QRX) can be described broadly as a black box that takes in an arbitrary quantum optical state along with classical coherent light, such as a local oscillator (LO), and extracts the complete phase space picture of the quantum state (quantum state tomography) with negligible contribution from classical noise sources.

In one embodiment of the disclosed invention, the QRX can be implemented as a modular tabletop device with off-the-shelf optical components and discrete electronics. In another embodiment, the QRX can be designed and fabricated on an integrated photonics platform, including but not limited to silicon, silica, lithium niobate, III-V semiconductors, diamond, oxides along with integrated electronics implemented on platforms, including but not limited to, silicon CMOS, gallium arsenide, germanium, silicon-germanium, and other semiconductors. In other embodiments, off-the-shelf optics with integrated electronics or integrated optics with discrete electronics can also be used to implement a QRX.

In one embodiment of the disclosed invention, the QRX utilizes optical ports to serve as inputs for the quantum optical state and the LO. For integrated photonic platforms, these ports can be grating couplers or edge couplers to couple light from a fiber to a nanophotonic waveguide. For tabletop optical components, these ports can be fiber-optic cables or free-space coupled links. In all of these embodiments, the novelty is in minimizing the contributions from classical noise sources, including but not limited to, mechanical noise, electrical noise, stray light, so that the quantum optical state to be received by the QRX can be accurately measured. The accurate measurement of the quantum optical state can be used to encode and decode quantum information in optical links.

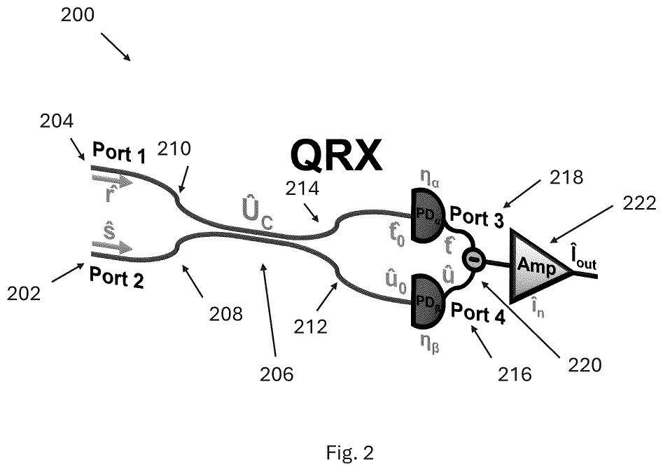

FIG. 2 illustrates an embodiment of the disclosed invention wherein the QRX has a coupler, ideally with 50:50 coupling, to interfere the quantum optical state with the coherent LO. After interference, the two outputs from the coupler are sent to two photodetectors (PD) with balanced characteristics. These photodetectors can be, including but not limited to, semiconductor photodiodes such as p-n junction photodiodes, PN, PIN, p-type-intrinsic layer-n-type layer photodiodes, avalanche photodiodes, photomultiplier tubes, photoconductive detectors, thermocouple detectors, thermopile detectors, pyroelectric detectors, transition edge sensors, superconducting nanowire single photon detectors. The photodetectors convert the optical signal to two electrical signals that are then subtracted from each other to remove any common-mode artifacts in the system. In some embodiments of the disclosed invention, meandering optical paths or various physical layout designs can be used to make the QRX as compact as possible with a trade-off for optical loss for large-scale quantum optoelectronic systems. A rigorous mathematical analysis of the optoelectronic transformation of a quantum optical state with a coherent LO is as follows.

Let \hat{l} and ŝ be the annihilation operators for the light impinging on the LO and signal antennas, respectively. After the LO phase shifter, \hat{r}=\hat{l}e^{iφ}^{_{PS}}. In the Heisenberg picture, we write the unitary operator for a directional coupler for two cases.

Balanced Case: For the balanced case,

$${\hat{U}}_{c} = exp [ i \frac{π}{4} ( {\hat{r}}^{†} \hat{s} + {\hat{r}}^{†} {\hat{s}}^{†} ) ] \qquad ( 1 )$$

$$and$$

$$[ \begin{matrix}{\hat{t}}_{0} \\ {\hat{u}}_{0}\end{matrix} ] = {\hat{U}}_{c}^{†} [ \begin{matrix}\hat{r} \\ \hat{s}\end{matrix} ] {\hat{U}}_{c} \qquad ( 2 )$$

$$Then ,$$

$${\hat{t}}_{0} = \frac{1}{\sqrt{2}} ( \hat{r} + \hat{s} ) \qquad ( 3 )$$

$${\hat{u}}_{0} = \frac{1}{\sqrt{2}} ( \hat{r} - \hat{s} ) \qquad ( 4 )$$

Photodetectors output a current proportional to the photon number (I_{PD}= [symbol] â^{†â} [symbol] ^{), and balanced PD pair output a current that is the difference of the currents on both branches. The loss and imperfect quantum efficiency of the photodetectors can be modeled as mixing the field operators with vacuum. Then,}

$$\hat{t} = \sqrt{η} {\hat{t}}_{0} + i ( \sqrt{1 - η} ) {\hat{v}}_{α} \qquad ( 5 )$$

$$\hat{u} = \sqrt{η} {\hat{u}}_{0} + i ( \sqrt{1 - η} ) {\hat{v}}_{β} \qquad ( 6 )$$

where η is the quantum efficiency of the photodiode combined with all other lumped losses, and \hat{v} is the field operator for the mixed vacuum. Then,

$${\hat{I}}_{out} = η [ \frac{1}{2} ( {\hat{t}}^{†} \hat{t} - {\hat{u}}^{†} \hat{u} ) + \frac{\sqrt{1 - η}}{\sqrt{η}} V ] \qquad ( 7 )$$

$$= η [ \frac{1}{2} ( {\hat{r}}^{†} + {\hat{s}}^{†} ) ( \hat{r} + \hat{s} ) - \frac{1}{2} ( {\hat{r}}^{†} - {\hat{s}}^{†} ) ( \hat{r} - \hat{s} ) + \frac{\sqrt{1 - η}}{\sqrt{η}} V ] \qquad ( 8 )$$

$$= η [ \frac{1}{2} ( {\hat{r}}^{†} \hat{r} + {\hat{r}}^{†} \hat{s} + {\hat{s}}^{†} \hat{r} + {\hat{s}}^{†} \hat{s} ) - \frac{1}{2} ( {\hat{r}}^{†} \hat{r} - {\hat{r}}^{†} \hat{s} - {\hat{s}}^{†} \hat{r} + {\hat{s}}^{†} \hat{s} ) + \frac{\sqrt{1 - η}}{\sqrt{η}} V ] \qquad ( 9 )$$

$$= η ( {\hat{r}}^{†} \hat{s} + {\hat{s}}^{†} \hat{r} + \frac{\sqrt{1 - η}}{\sqrt{η}} V ) \qquad ( 10 )$$

where V denotes the vacuum terms. Substituting in coherent state for \hat{r}=I_{LO}e^{(ω}^{_{LO}}^{t+φ}^{_{LO}}⁾,

$${\hat{I}}_{Out} = η {I}_{L O} [ {e}^{- i ( {ω}_{L O} t + {Φ}_{L O} )} \hat{s} + {\hat{s}}^{†} {e}^{i ( {ω}_{L O} t + {Φ}_{L O} )} ] + \sqrt{η} \sqrt{1 - η} V \qquad ( 11 )$$

$$= η {I}_{L O} [ \hat{s} {e}^{- i {ω}_{LO} t} {e}^{i Ψ} + {\hat{s}}^{†} {e}^{i {ω}_{LO} t} {e}^{- i Ψ} ] + \sqrt{η} \sqrt{1 - η} V \qquad ( 12 )$$

$$where Ψ = {Φ}_{L O} . Defining {\hat{s}}^{†} = {\hat{s}}_{0} {e}^{i {ω}_{s} t} , and neglecting vaccum terms$$

$${\hat{I}}_{out} = η {I}_{L O} ( {\hat{s}}_{0} {e}^{- i {ω}_{IF} t} {e}^{i Ψ} + {\hat{s}}_{0}^{†} {e}^{i {ω}_{IF} t} {e}^{- i Ψ} ) \qquad ( 13 )$$

$$= 2 η {I}_{L O} {\hat{X}}_{{ω}_{IF}} ( Ψ ) \qquad ( 14 )$$

where \hat{X}_{ω}_{_{IF}}(Ψ) is the field quadrature operator of the signal at the angle Ψ propagating at a frequency of ω_{IF}

$${\hat{X}}_{{ω}_{IF}} ( Ψ ) = \frac{1}{2} ( {\hat{s}}_{0} {e}^{- i {ω}_{IF} t} {e}^{i Ψ} + {\hat{s}}_{0}^{†} {e}^{i {ω}_{IF} t} {e}^{- i Ψ} ) \qquad ( 15 )$$

By measuring the signal at ω_{IF}, information about the field quadrature at that sideband can be extracted.

Unbalanced Case: For the unbalanced case,

$${\hat{U}}_{c} = α β exp [ i \frac{π}{4} ( {\hat{r}}^{†} \hat{s} + {\hat{r}}^{†} {\hat{S}}^{†} ) ] \qquad ( 16 )$$

$$and$$

$$[ \begin{matrix}{\hat{t}}_{0} \\ {\hat{u}}_{0}\end{matrix} ] = {\hat{U}}_{c}^{†} [ \begin{matrix}\hat{r} \\ \hat{s}\end{matrix} ] {\hat{U}}_{c} \qquad ( 17 )$$

$$Then ,$$

$${\hat{t}}_{0} = α \hat{r} + β \hat{s} \qquad ( 18 )$$

$${\hat{u}}_{0} = β \hat{r} - α \hat{s} \qquad ( 19 )$$

where α²+β²=1. Photodetectors output a current proportional to the photon number (I_{PD}= [symbol] â^{†}â, and balanced PD pair output a current that is the difference of the currents on both branches. Then,

The loss and imperfect quantum efficiency of the photodetectors can be modeled as mixing the field operators with vacuum. Then,

$$\hat{t} = \sqrt{{η}_{α}} {\hat{t}}_{0} + i ( \sqrt{1 - {η}_{α}} ) {\hat{v}}_{α} \qquad ( 20 )$$

$$\hat{u} = \sqrt{{n}_{β}} {\hat{u}}_{0} + i \sqrt{1 - {η}_{β}} ) {\hat{v}}_{β} \qquad ( 21 )$$

where η is the quantum efficiency of the photodiode combined with all other lumped losses, and \hat{v} is the field operator for the mixed vacuum. Then,

$${\hat{I}}_{out} = {η}_{α} ( {\hat{t}}^{†} \hat{t} + \frac{\sqrt{1 - {η}_{α}}}{\sqrt{{η}_{α}}} {V}_{α} ) - {η}_{β} ( {\hat{u}}^{†} \hat{u} + \frac{\sqrt{1 - {η}_{β}}}{\sqrt{{η}_{β}}} {V}_{β} ) \qquad ( 22 )$$

$$= {η}_{α} [ \frac{1}{2} ( α {\hat{r}}^{†} + β {\hat{s}}^{†} ) ( α \hat{r} + β \hat{s} ) + \frac{\sqrt{1 - {η}_{α}}}{\sqrt{{η}_{α}}} {V}_{α} ] - {η}_{β} [ \frac{1}{2} ( β {\hat{r}}^{†} - α {\hat{s}}^{†} ) ( β \hat{r} - α \hat{s} ) + \frac{\sqrt{1 - {η}_{β}}}{\sqrt{{η}_{β}}} {V}_{β} ] \qquad ( 23 )$$

$$= {η}_{α} [ \frac{1}{2} ( {α}^{2} {\hat{r}}^{†} \hat{r} + α β {\hat{r}}^{†} \hat{s} + αβ {\hat{s}}^{†} \hat{r} + {β}^{2} {\hat{s}}^{†} \hat{s} ) + \frac{\sqrt{1 - {η}_{α}}}{\sqrt{{η}_{α}}} {v}_{α} ] \qquad ( 24 )$$

$$- {η}_{β} [ \frac{1}{2} ( {β}^{2} {\hat{r}}^{†} \hat{r} - α β {\hat{r}}^{†} \hat{s} - α β {\hat{s}}^{†} \hat{r} + {α}^{2} {\hat{s}}^{†} \hat{s} ) + \frac{\sqrt{1 - {η}_{β}}}{\sqrt{{η}_{β}}} {V}_{β} ] \qquad ( 25 )$$

$$= {Σ}_{α} {\hat{r}}^{†} \hat{r} - {Σ}_{β} {\hat{s}}^{†} \hat{s} + Π ( {\hat{r}}^{†} \hat{s} + {\hat{s}}^{†} \hat{r} ) + \sqrt{{η}_{α}} \sqrt{1 - {η}_{α}} {V}_{α} + \sqrt{{η}_{β}} \sqrt{1 - {η}_{β}} {v}_{β} \qquad ( 26 )$$

$$= {Σ}_{α} {\hat{r}}^{†} \hat{r} - {Σ}_{β} {\hat{s}}^{†} \hat{s} + Π ( {\hat{r}}^{†} \hat{s} + {\hat{s}}^{†} \hat{r} ) + V \qquad ( 27 )$$

where Σ_{α}=α²η_{α}−β²η_{β}, Σ_{β}=β²η_{α}−α²η_{β} and Π=(η_{α}+η_{β})αβ. Substituting in coherent state for \hat{r}=|I_{LO}e^{i(ω}^{_{LO}}^{t+φ}^{_{LO}}⁾ [symbol] ,

$${\hat{I}}_{out} = {Σ}_{α} {I}_{L O}^{2} - {Σ}_{β} {\hat{s}}^{†} \hat{s} + i Π {I}_{L O} [ {e}^{- i ( {ω}_{LO} t + {Φ}_{LO} )} \hat{s} + {\hat{s}}^{†} {e}^{i ( {ω}_{LO} t + {Φ}_{LO} )} ] + V \qquad ( 28 )$$

$$= {Σ}_{α} {I}_{L O}^{2} - {Σ}_{β} {\hat{s}}^{†} \hat{s} + Π {I}_{L O} [ \hat{s} {e}^{- i ( {ω}_{L O} t + {Φ}_{L O} - π / 2 )} + {\hat{s}}^{†} {e}^{i ( {ω}_{L O} t + {Φ}_{L O} - π / 2 )} ] + V \qquad ( 29 )$$

$$= {Σ}_{α} {I}_{L O}^{2} - {Σ}_{β} {\hat{s}}^{†} \hat{s} + Π {I}_{L O} [ \hat{s} {e}^{- i {ω}_{L O} t} {e}^{i Ψ} + {\hat{s}}^{†} {e}^{i {ω}_{L O}} {e}^{- i Ψ} ] + V \qquad ( 30 )$$

$$where Ψ = {Φ}_{L O} . Defining \hat{s} = {\hat{s}}_{0} {e}^{i {ω}_{s} t} ,$$

$${\hat{I}}_{out} = {Σ}_{α} {I}_{L O}^{2} - {Σ}_{β} {\hat{s}}^{†} \hat{s} + Π {I}_{L O} ( {\hat{s}}_{0} {e}^{- i {ω}_{IF} t} {e}^{i Ψ} + {\hat{s}}_{0}^{†} {e}^{i {ω}_{IF} t} {e}^{- i Ψ} ) + V \qquad ( 31 )$$

$$= {Σ}_{α} {I}_{L O}^{2} - {Σ}_{β} {\hat{s}}^{†} \hat{s} + 2 Π {I}_{L O} {\hat{X}}_{{ω}_{IF}} ( Ψ ) + V \qquad ( 32 )$$

where \hat{X}_{ω}_{_{IF}}(Ψ) is the field quadrature operator of the signal at the angle Ψ propagating at a frequency of ω_{IF}.

$${\hat{X}}_{{ω}_{IF}} ( Ψ ) = \frac{1}{2} ( {\hat{s}}_{0} {e}^{- i {ω}_{IF} t} {e}^{i Ψ} + {\hat{s}}_{0}^{†} {e}^{i {ω}_{IF} t} {e}^{- i Ψ} ) \qquad ( 33 )$$

At a high LO power limit, ŝ^{†}ŝ can be neglected, and we also neglect the vacuum terms for simplicity.

$${\hat{I}}_{out} = Σ {I}_{L O}^{2} + 2 Π {I}_{L O} {\hat{X}}_{{ω}_{IF}} ( Ψ ) \qquad ( 34 )$$

We introduce another operator, \hat{l}ₙ to specify the noise from the amplifiers and readout electronics and other current noise such as dark current. Furthermore,

$${P}_{L O} = {I}_{L O}^{2}$$

is the optical power of LO. Then,

$${\hat{I}}_{out} = Σ {P}_{L O} + 2 Π \sqrt{{P}_{L O}} {\hat{X}}_{{ω}_{IF}} ( Ψ ) + {\hat{ι}}_{n} \qquad ( 35 )$$

$$Dividing by \sqrt{{P}_{L O}} ,$$

$$\frac{{\hat{I}}_{out}}{{P}_{L O}} = Σ \sqrt{{P}_{L O}} + 2 Π {\hat{X}}_{{ω}_{IF}} ( Ψ ) + \frac{{\hat{ι}}_{n}}{\sqrt{{P}_{L O}}} \qquad ( 36 )$$

By minimizing the first term toward zero, the unbalanced case approaches the balanced case expression, and by minimizing the third term, the parasitic from other noise is filtered, allowing an accurate quantum state tomography of the input quantum state. Therefore, one of the novelties of the QRX from a standard interferometer or coherent optical receiver is significant minimization of these terms that the second term dominates.

### 2.1 Optoelectronic Specifications

With this objective in mind, we derive optoelectronic specs to design and characterize QRX. We connect (36) to S-parameters used in the characterization of optoelectronic systems. Since the QRX is a four-port device before current subtraction, an optoelectronic S-parameter matrix can be derived for all four ports of the system.

$$S = [ \begin{matrix}{S}_{11} & {S}_{12} & {S}_{13} & {S}_{14} \\ {S}_{21} & {S}_{22} & {S}_{23} & {S}_{24} \\ {S}_{31} & {S}_{32} & {S}_{33} & {S}_{34} \\ {S}_{41} & {S}_{42} & {S}_{43} & {S}_{44}\end{matrix} ] \qquad ( 37 )$$

Elements that relate ports 1 and 2 are optical S-parameters that characterize the linear optical transformations between the input optical power waves of the system. Elements that relate ports 3 and 4 are RF S-parameters that characterize the linear RF transformations between the output RF power waves of the system. The rest of the elements are optoelectronic S-parameters that characterize the transformations between the input power waves to output currents. We can relate the analysis in the previous section to S-parameters as

$${S}_{31} = {α}^{2} {η}_{α} \qquad ( 38 )$$

$${S}_{32} = {β}^{2} {η}_{α} \qquad ( 39 )$$

$${S}_{41} = {β}^{2} {η}_{β} \qquad ( 40 )$$

$${S}_{42} = {α}^{2} {η}_{β} \qquad ( 41 )$$

$$Therefore ,$$

$${\sum }_{α} = {S}_{31} - {S}_{41} \qquad ( 42 )$$

$${\sum }_{β} = {S}_{32} - {S}_{42} \qquad ( 43 )$$

$$Π = \sqrt{\frac{{η}_{α}}{{η}_{β}} {S}_{42} {S}_{32}} + \sqrt{\frac{{η}_{β}}{{η}_{α}} {S}_{42} {S}_{32}} = \sqrt{{S}_{42} {S}_{41}} + \sqrt{{S}_{32} {S}_{31}} \qquad ( 44 )$$

CMRR: Since the coherent and macroscopic amplification of the quantum statistics come from the mixed terms in the output currents, minimizing the common-mode terms allow for minimizing the classical noise sources in the system. Therefore, the common-mode rejection ratio (CMRR) is one specification of a QRX to benchmark its performance. With this, we derive the CMRR as

$$CMRR = \frac{\sum }{Π} = \frac{\vert {S}_{31} - {S}_{41} \vert}{\sqrt{{S}_{42} {S}_{41}} + \sqrt{{S}_{32} {S}_{31}}} \qquad ( 45 )$$

CMRR must be minimized for the first term in (36) to vanish.

We define all optical powers by a random variable P that can be split into signal-carrying and noise-carrying components, i.e. P=p+δp·p= [symbol] P [symbol] =ℏω [symbol] n [symbol] is the mean optical power corresponding to a mean photon number, [symbol] n [symbol] , and δp=P− [symbol] P [symbol] is the random variable corresponding to shot noise. Then, for Poissonian light with large [symbol] n [symbol] , [symbol] δp² [symbol] =(ℏ\sqrt{ωn})²=ℏωp, where ℏω is the photon energy per bandwidth. Then,

$${P}_{signal} = {〈 {\hat{I}}_{o u t} 〉}^{2} = 4 {\sum }^{2} {〈 \sqrt{{p}_{s} + δ {p}_{s}} \sqrt{{p}_{L O} + {δ}_{{P}_{L O}}} 〉}^{2} \approx 4 {\sum }^{2} {P}_{s} {P}_{L O} \qquad ( 46 )$$

$$〈 Δ {\hat{I}}_{out}^{2} 〉 \approx {\sum }_{β}^{2} 〈 δ {p}_{s}^{2} 〉 + {\sum }_{α}^{2} 〈 δ {p}_{L O}^{2} 〉 + 2 {\sum }_{β} {\sum }_{α} 〈 δ {p}_{s} δ {p}_{LO} 〉 \qquad ( 47 )$$

$$+ 4 {Π}^{2} ( \frac{{p}_{s} 〈 δ {p}_{L O}^{2} 〉}{4 {p}_{L O}} + \frac{{p}_{L O} 〈 δ {p}_{s}^{2} 〉}{4 {p}_{s}} + \frac{〈 δ {p}_{s} δ {p}_{L O} 〉}{2} ) + 〈 δ {i}_{n}^{2} 〉 \qquad ( 48 )$$

At high LO powers, only terms linear with p_{LO} dominate.

$${P}_{n o i s e} = 〈 Δ {\hat{I}}_{out}^{2} 〉 + 〈 δ {i}_{n}^{2} 〉 \approx {\sum }^{2} 〈 δ {p}_{L O}^{2} 〉 + {Π}^{2} ( \frac{{p}_{L O} 〈 δ {p}_{s}^{2} 〉}{{p}_{s}} ) + 〈 δ {i}_{n}^{2} 〉 \qquad ( 49 )$$

Normalizing by p_{LO}

$$\frac{{P}_{n o i s e}}{{p}_{L O}} = {\sum }^{2} \frac{〈 δ {p}_{L O}^{2} 〉}{{p}_{L O}} + {Π}^{2} \frac{〈 δ {p}_{s}^{2} 〉}{{p}_{s}} + \frac{〈 δ {i}_{n}^{2} 〉}{{p}_{LO}} \qquad ( 50 )$$

Here,

$$〈 δ {p}_{L O}^{2} 〉$$

is comprised of LO shot noise as well as additional relative intensity noise. Therefore,

$$〈 δ {p}_{LO}^{2} 〉 = ( 1 + RIN {p}_{LO} ) ℏ ω {p}_{LO} .$$

### Then,

$$\frac{{P}_{n o i s e}}{{p}_{L O}} = ( \frac{1 + {RIN}^{2} {p}_{L O}}{C M R {R}^{2}} + 1 ) {Π}^{2} ℏ ω + \frac{〈 δ {i}_{n}^{2} 〉}{{p}_{LO}} \qquad ( 51 )$$

Hence, LO power knee Pₖₙₑₑ is

$${P}_{k n e e} = \frac{〈 δ {i}_{n}^{2} 〉}{{Π}^{2} ℏ ω ( 1 - \frac{1}{{CMRR}^{2}} )} \qquad ( 52 )$$

SNC: The third specification is the shot noise clearance (SNC) that characterizes how much the third term can be minimized at most before the QRX saturates with maximum LO power (Pₘₐₓ). Hence,

$$S N C = \frac{{P}_{max}}{{P}_{k n e e}} \qquad ( 53 )$$

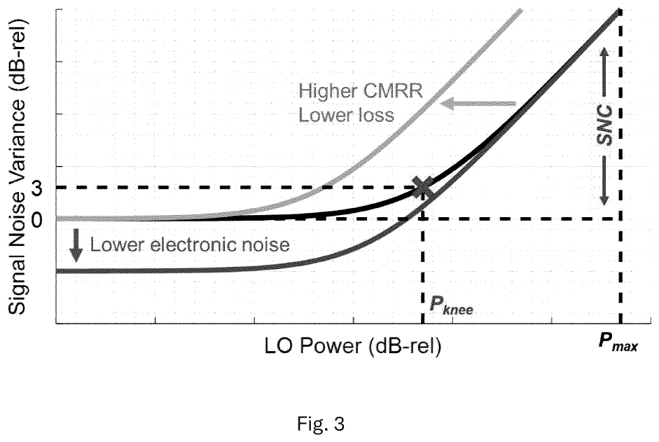

The trade-offs between these three specifications are shown in FIG. 3.

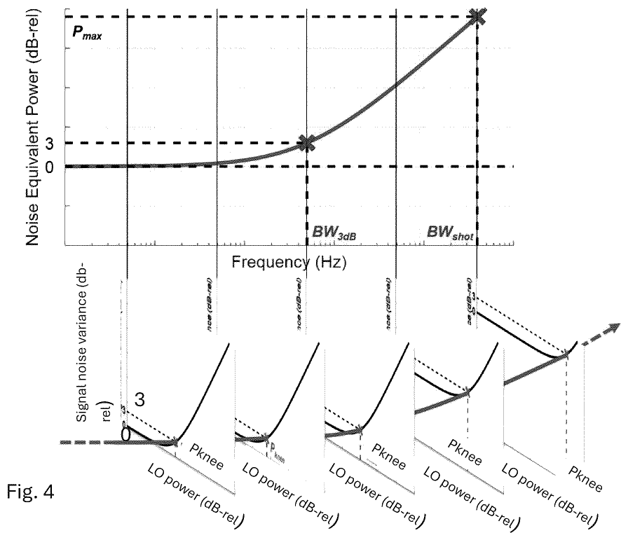

Optoelectronic bandwidth: These three specifications (specs) are defined for a single RF frequency of operation. As an extension, these specs can also be defined for every ω_{IF} depending on the RF bandwidth of operation for the QRX. Due to finite electronic response time, the QRX has finite RF bandwidth. We define two bandwidth parameters which are characterized by extending the S-parameters to include the noise equivalent power. As seen in FIG. 4, noise equivalent power (NEP) is defined as the Pₖₙₑₑ of QRX at a given frequency. By plotting Pₖₙₑₑ across all frequencies, QRX can be fully characterized.

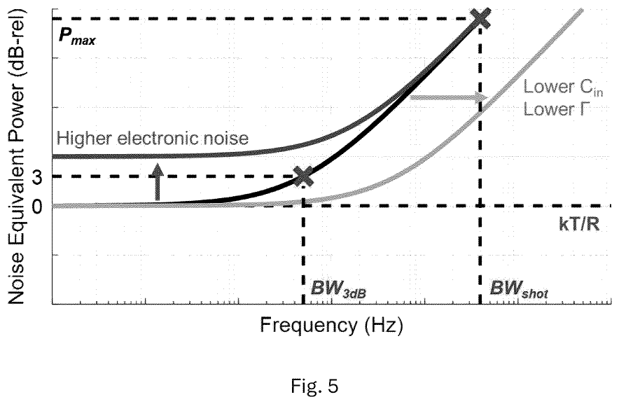

The 3-dB bandwidth of the device (BW_{3 dB}) is defined to be the RF frequency when the NEP rises by 3 dB. The other bandwidth is reached when the NEP reaches Pₘₐₓ. We define this bandwidth to be the shot-noise-limited bandwidth (BWₛₕₒₜ). The trade-off for this spec is shown in FIG. 5.

Optical bandwidth: Optical bandwidth of the QRX is specified by the operating wavelength range of the optical components of the QRX. Although the optoelectronic bandwidth is usually smaller than the optical bandwidth, tunable LO frequency can allow multiple frequency ranges of a broadband quantum optical state to be probed. In some embodiments of the disclosed invention, broadband photodetectors can be used with high quantum efficiency over a broad range of optical wavelengths to extend the optical bandwidth. In some embodiments of the disclosed invention, broadband couplers such as, including but not limited to, grating assisted couplers, rapid adiabatic couplers, dispersion engineered couplers, can be used to extend the optical bandwidth.

Extending the optical bandwidth of the QRX allows more complex LO sources to be used for probing broadband quantum optical states. In one embodiment of the disclosed invention, a wavelength tunable LO source can be used to probe a different frequency range of the quantum optical state in a time-multiplexed manner. In another embodiment of the disclosed invention, a broadband LO source such as, including but not limited to, frequency comb source, supercontinuum source, can be used to probe multiple frequency ranges of the quantum optical state at once, although since they are probed simultaneously the optoelectronic signatures of different frequency ranges would be coherently summed at the QRX output. In all of these embodiments the LO and signal should maintain their phase coherence.

These five specs (CMRR, Pₖₙₑₑ, SNC, optoelectronic bandwidth, and optical bandwidth) fully characterize the optoelectronic performance of a QRX and also distinguish standard interferometers from QRXs. Improving CMRR allows higher noise LO to be used in the quantum optoelectronic system. Improving Pₖₙₑₑ allows the QRX to operate at lower power and facilitates the scaling of QRX arrays for large-scale quantum optoelectronic systems. Improving SNC increases the dynamic range of the QRX and allows operation with higher noise electronics and photodetectors. Improving optoelectronic bandwidth allows higher rate operation of the QRX to probe a wider range of optical sidebands of a quantum optical state with respect to LO frequency. Improving optical bandwidth allows the detection of a quantum optical state over a broader range of optical frequencies.

### 3. Auto-CMRR Correction

Keeping the CMRR minimized is a critical challenge for QRXs. Without sufficient CMRR, both Pₖₙₑₑ and SNC are worsened as seen in (52) and (53), compromising the QRX's non-classical light detection capability and reducing the overhead in information capacity above the classical limit in a quantum coherent communication link.

In one embodiment of the disclosed invention, the coupler is a tunable coupler in the form of a Mach-Zehnder interferometer (MZI) with one or more phase shifters to tune the coupling ratio. The phase shifter can be any type of phase shifter to tune the phase, such as, including but not limited to, thermo-optic, electro-optic or optomechanical. For an LO in the form of a coherent state, the electrical signal after photodetection in the QRX can be used to probe the imperfect CMRR of the QRX since, in the limit of infinite LO power, a perfect CMRR would cancel all of the LO noise contribution in the output. This LO contribution can then be used as an error signal to be fed back to the one or more phase shifters in the MZI to automatically correct the CMRR until the error signal is minimized up to the extinction ratio of this auto-CMRR correction loop. In one embodiment of the disclosed invention, the MZI and light routing up to the photodetectors is designed to be symmetrical to reduce the imbalance in the impulse response of the optical propagation paths and the imbalance in loss.

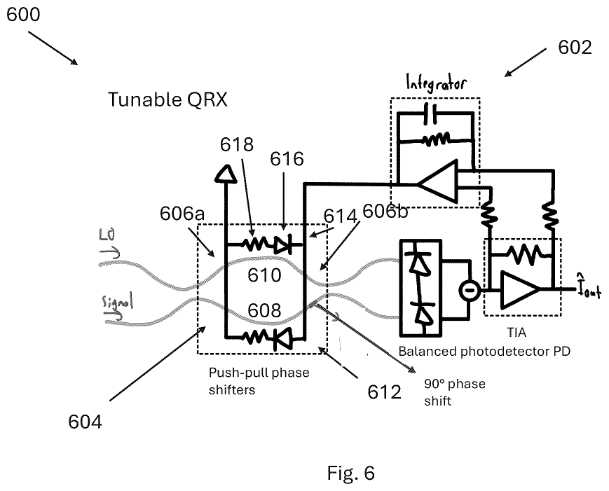

In another embodiment of the disclosed invention, a 90° optical phase shift can be added to one of the branches to make the MZI 50:50 by default without tuning to have the option not to use the CMRR correction, saving optoelectronic complexity. In another embodiment of the disclosed invention, a phase shifter on each branch of the MZI can be used with a push-pull mechanism to reduce the footprint of the MZI. The push-pull allows both positive and negative voltages to be used in the phase tuning by having phase shifters with diodes. Positive voltage leads to one phase shifter to be “on” since its diode conducts current, while the other stays off since its diode doesn't conduct current and vice versa. By doubling the voltage range the phase tuning can use, the footprint of the phase shifting region can decrease. An example tunable QRX using this auto-CMRR correction with unmodulated LO using the LO power as the error signal is shown in FIG. 6.

In yet another embodiment of the disclosed invention, LO can be unmodulated and any LO signature in the output can be used as the error signal, such as, including but not limited to, DC signal from constant LO power, spontaneous emission noise, amplified spontaneous emission noise, any amplitude fluctuations at any frequency in the LO. In yet another embodiment of the disclosed invention, LO can be modulated with a signal at a known frequency and a mixer-based electronic circuitry, such as, including but not limited to, a lock-in amplifier, homodyne/heterodyne detector, can be used to extract the amplitude of the signal from the LO carrier. The downconverted signal becomes the error signal.

This correction mechanism should add minimal loss to the system. In another embodiment of the disclosed invention, two MZIs after a non-tunable coupler can also be used to attenuate one coupler output with respect to another but since this adds more losses than the other method, this shouldn't be preferred.

In another embodiment of the disclosed invention, tuning can also be added to the photodetectors to tune and match their impulse responses. While the aforementioned control system would improve the CMRR up to the bandwidth of the feedback loop, this would ensure a more broadband CMRR correction by matching the S₃₁ and S₄₁ over the entire optoelectronic bandwidth of the QRX. This tuning in photodetectors should add minimal loss. In one embodiment where photodiodes are used, this tuning can be in the bias voltage since this tunes the transit time of the photo-excited carriers in the photodiodes. However, photodiodes should be carefully designed since a high bias voltage combined with a high power LO can distort the electric field in the depletion region of the photodiodes due to the carrier screening effect, in turn increasing the transit time. This would reduce the Pₘₐₓ of the QRX.

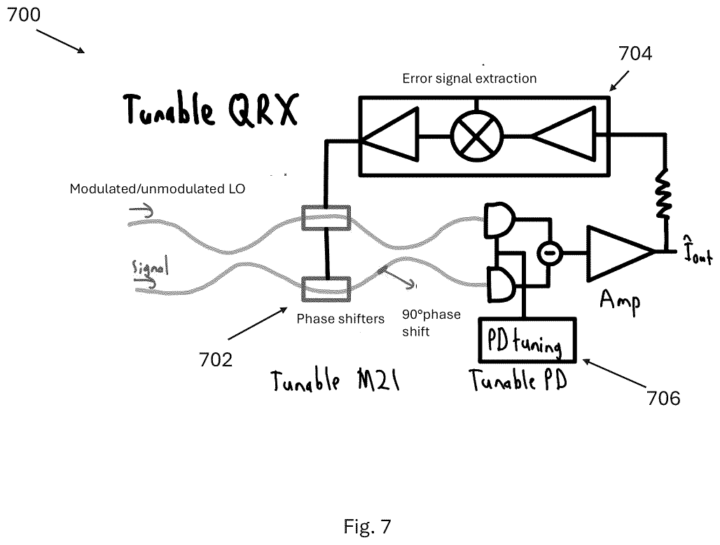

Therefore, the approach for a QRX with the best auto-CMRR correction design is a combination of both aforementioned methods (tunable coupler and tunable photodiodes). A high-level diagram and summary of a tunable QRX with auto-CMRR correction can be seen in FIG. 7.

### 4. Silicon Photonic Quantum Coherent Receiver

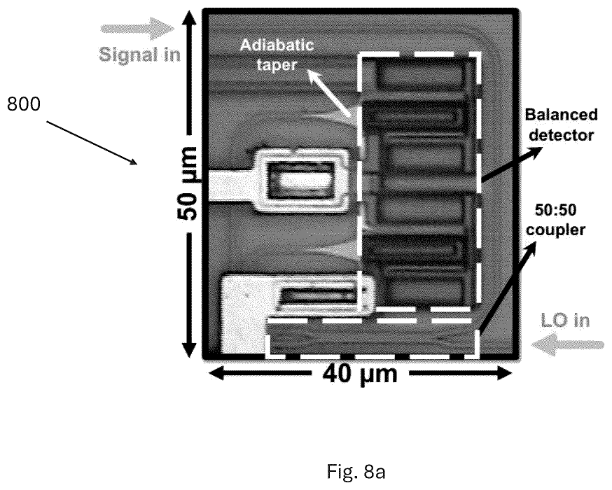

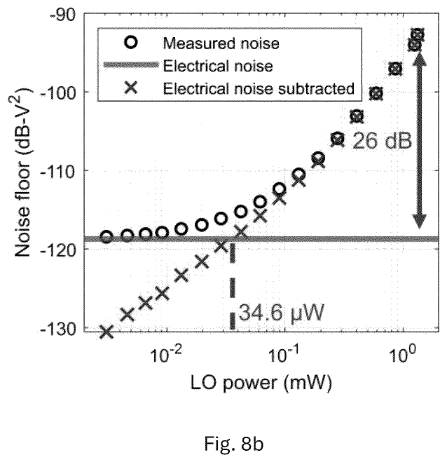

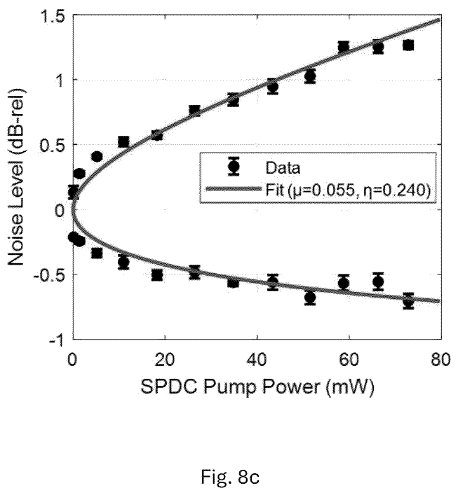

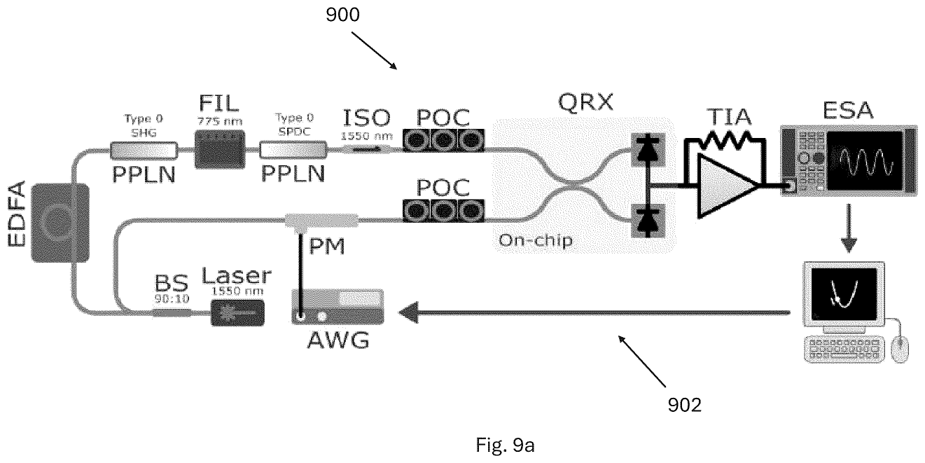

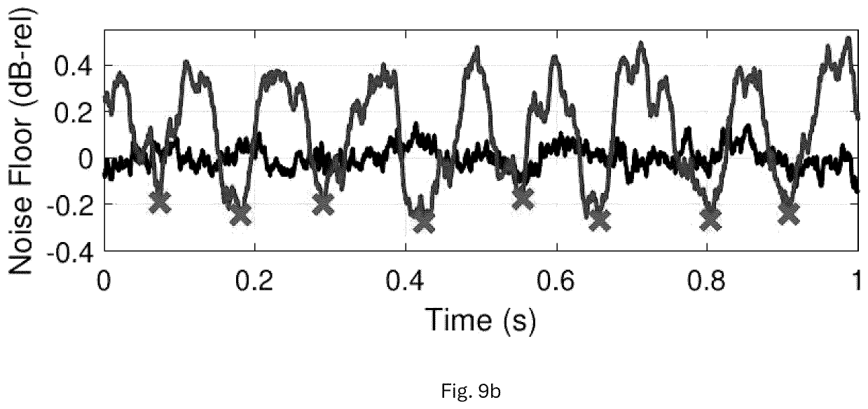

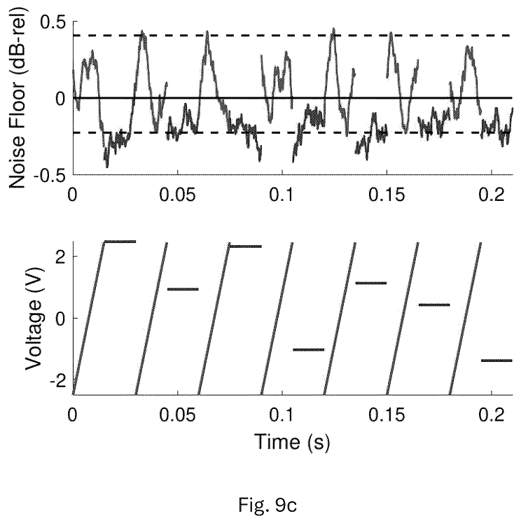

FIGS. 8a and 9a illustrates an example of a QRX manufactured on an integrated photonic platform [4] and comprising a silicon photonic chip hosting a photonic integrated circuit (PIC) and a trans-impedance amplifier (TIA) on a printed circuit board (PCB). On the PIC, two grating couplers are used to couple signal and local oscillator (LO) light into on-chip waveguides routed to a 50:50 directional coupler. The coupler mixes the signal and LO and sends the resulting light to two matched on-chip Ge photodiodes. Electrical outputs from the photodiodes are subtracted on-chip, and the resulting output is amplified using the TIA.

The micrograph of the compact photonic chip in FIG. 8a shows the integrated receiver has a core chip area of 0.00200 mm² (50 μm×40 μm), making it the smallest detector with demonstrated quantum light detection capability. As seen in FIG. 9b, the QRX has 26.0 dB SNC and 34.6 μWPₖₙₑₑ with a noise floor integrated over 3 MHz of bandwidth.

The QRX was used to detect squeezed vacuum and demonstrate an easy-to-deploy phase-locking approach to lock onto the squeezed quadrature with the setup shown in FIG. 9a. This phase locking is used to demonstrate the consistent reduction of the shot noise floor that limits conventional classical coherent communications. The squeezed vacuum was generated with a periodically-poled lithium niobate (PPLN) waveguide. The PPLN was characterized with a tabletop coherent receiver. As seen in FIG. 9c, the μ from the fit is 0.055 mW^{1/2}, which characterizes the squeezing parameter of the waveguide, given by r=μ\sqrt{P}, where P is the SPDC pump power. The measured noise level at phase θ is then characterized by

$$Δ {X}_{m}^{2} ( θ ) = η [ {e}^{2 r} {cos}^{2} θ + {e}^{- 2 r} {sin}^{2} θ ] + 1 - η ,$$

where η is the detection efficiency. After source characterization, squeezed vacuum was coupled to chip, and noise floor oscillations in the output with 4 Hz LO phase modulation were measured with an electrical spectrum analyzer (ESA). A 100-second trace was recorded for both squeezed vacuum (red) and vacuum (black). A 1-second section of this data is shown in FIG. 9b. Over 100 seconds, noise floors 0.226±0.096 dB below and 0.408±0.146 dB above shot noise level (SNL) were observed.

Phase locking in quantum coherent receivers is useful for reaching sub-shot-noise-limited sensitivities with squeezed light and enabling phase-determinate quantum state tomography. A software-based phase-locking process can be useful for easily deploying coherent quantum links without the need for additional hardware in a quantum coherent transceiver system. Therefore, a phase-locking algorithm was employed to phase-lock the squeezed vacuum detected on-chip to its squeezed quadrature. The algorithm utilizes the phase modulator to do a I phase sweep and finds the phase voltage setting for the squeezed quadrature. The voltage setting is then applied to set the phase to the squeezed quadrature. This procedure is repeated at 67 Hz, as shown in FIG. 9c. This closed-loop phase locking enables sustained operation at sensitivities below the shot noise floor.

### 5. Photonic-Electronic Quantum Coherent Receiver

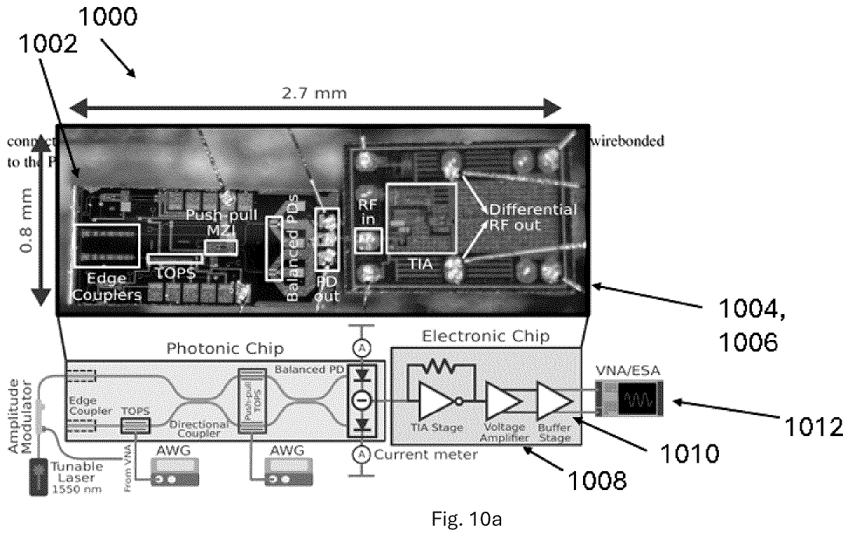

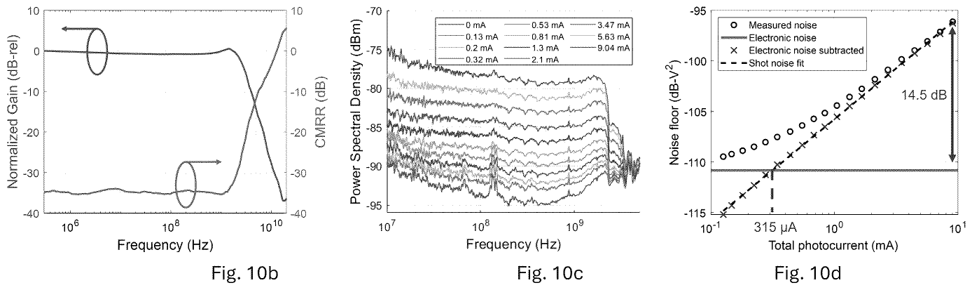

FIG. 10a illustrates another embodiment of a QRX on an integrated photonic-electronic platform [5], wherein the QRX comprises a silicon photonic chip hosting a photonic integrated circuit (PIC) and a trans-impedance amplifier (TIA) on a printed circuit board (PCB). The photonic integrated circuit (PIC) section of the QRX comprises two edge couplers with 127 μm pitch suitable for coupling the local oscillator (LO) and signal light with fiber arrays, a thermo-optic phase shifter (TOPS) for modulating the phase, a push-pull Mach-Zehnder interferometer (MZI) for interfering LO and signal and correcting the common-mode rejection ratio (CMRR), and a balanced pair of Ge photodiodes (PDs) for photodetection. The electronic integrated circuit (EIC) section of the QRX comprises a transimpedance amplifier (TIA), a voltage amplifier, and an output buffer with differential outputs. As seen in FIG. 10a, The PIC and EIC are packaged together on a custom PCB with a wirebond between the PIC RF output and EIC RF input. To minimize the bond wire parasitics before EIC amplification, pads on both chips were kept level and positioned as close together as possible. RF outputs from the EIC were wirebonded to transmission lines on the PCB matched to 5002. The transmission lines were connected to SMA

The packaged EPIC was first characterized to determine its bandwidth, CMRR, and shot noise clearance to ensure quantum-limited performance. Bandwidth and CMRR measurements were done as a three-port measurement with a 20 GHz vector network analyzer (VNA) connected to the differential outputs of the EIC and a 40 GHz amplitude modulator as seen in FIG. 10a. Current meters were connected to the DC bias lines of the PDs to monitor the PD photocurrents. The optoelectronic response of the QRX is shown in FIG. 10b, showing a 3-dB bandwidth of 2.57 GHz. The CMRR measurement was done by first tuning the MZI on the QRX so that all of the coupled light is illuminated on one PD for the unbalanced frequency response and then tuning the MZI so that both PDs have the same illumination for the balanced frequency response. Due to the dynamic changes in the coupling coefficients of the on-chip MZI dominated by the drifts in the polarization of the LO over time and the limited dynamic range of the setup, the measurement only gives an upper bound on the CMRR. Gain measurements from the two setups were processed to characterize the CMRR defined as

$$CMRR = 10 {log}_{10} ( \frac{2 {P}_{a b l}}{{P}_{unb}} ) ,$$

where
P_{bal} and P_{unb} are the balanced RF power and unbalanced RF power measurements, respectively. The resulting CMRR frequency response is seen in FIG. 10b, ensuring a CMRR lower than −35.4 dB.

Shot noise clearance measurements were done with an RF spectrum analyzer (ESA) by sweeping the LO power and measuring the RF spectrum of one of the differential outputs. The photocurrents were monitored to maximize the CMRR and minimize the LO shot noise and relative intensity noise from leaking in [3]. The measurements were also done in a Faraday cage to minimize RF interference from external sources. As seen in FIGS. 10c and 10d, the shot noise clearance is 14.5 dB over the bandwidth of the QRX.

The SNC frequency response with maximum LO photocurrent is seen in FIG. 11c, showing a shot-noise-limited bandwidth of 3.50 GHz. A shot noise line is also fitted to the electronic noise subtracted measurements showing a near-unity slope of 1.007±0.015, ensuring broadband quantum-limited performance.

The QRX was used to measure squeezed vacuum to demonstrate sub-shot-noise level operation up to the shot-noise-limited bandwidth. The squeezed vacuum was generated with two periodically-poled lithium niobate (PPLN) waveguides cascaded with reverse polarities for SHG and SPDC as seen in FIG. 11a. Squeezed vacuum was coupled to chip with a V-groove array. Noise floor oscillations in the output with 1 Hz LO phase modulation were measured with a spectrum analyzer at different sideband frequencies. 30-second traces were recorded for both squeezed vacuum (red) and vacuum (black) at each frequency. A 10-second section of the data measured at 1.17 GHz is shown in FIG. 11b. After data collection, a peak search algorithm was used to acquire the noise level for squeezed and antisqueezed quadratures normalized to the shot noise level (SNL) at each frequency as shown in FIG. 11d. A maximum squeezed noise of 0.156±0.039 dB below the SNL and a maximum anti-squeezed noise of 0.507±0.052 above the SNL were observed.

While we were limited by the source and tabletop component losses in the squeezed light measurements, on-chip loss sets the bound on how much squeezing can be observed with the QRX. The on-chip system loss comprises the optical losses and the optoelectronic loss determined by the shot noise clearance and PD quantum efficiency (QE). The QRX has a total optical loss of 2.7 dB with 1.3 dB from edge couplers, 1.4 dB from PD QE, and a negligible amount of loss from the TOPS, MZI, and routing. As shown in FIG. 11c, the shot noise clearance is also greater than 10 dB up to 2.24 GHz. Therefore, the system loss is at most 3 dB over the bandwidth of the receiver, enabling sensitivities of 3 dB below the SNL (shot noise level).

### 6. Quantum Coherent Receiver Arrays

In another embodiment of the disclosed invention, quantum coherent receiver arrays can be developed for spatiotemporal multiplexing in the measurement of quantum signals. Quantum information can be encoded in different spatiotemporal modes of light and received by QRX arrays. In one embodiment of the disclosed invention, QRX arrays can enable reconfigurability in control of different spatiotemporal modes of quantum signals. In one embodiment, this reconfigurability can be leveraged to filter signals with certain spatiotemporal profiles. In another embodiment, this reconfigurability can be used to increase the information capacity of the quantum channel by increasing rate of measurement. Other functionalities arising from this reconfigurability and multiplexing will also be enabled by QRX arrays.

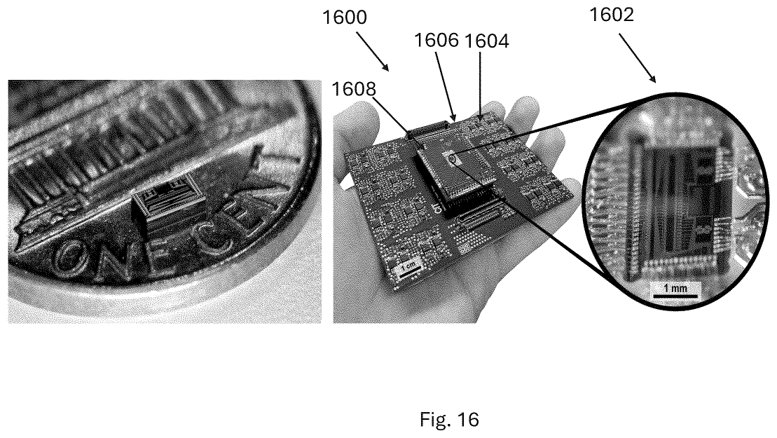

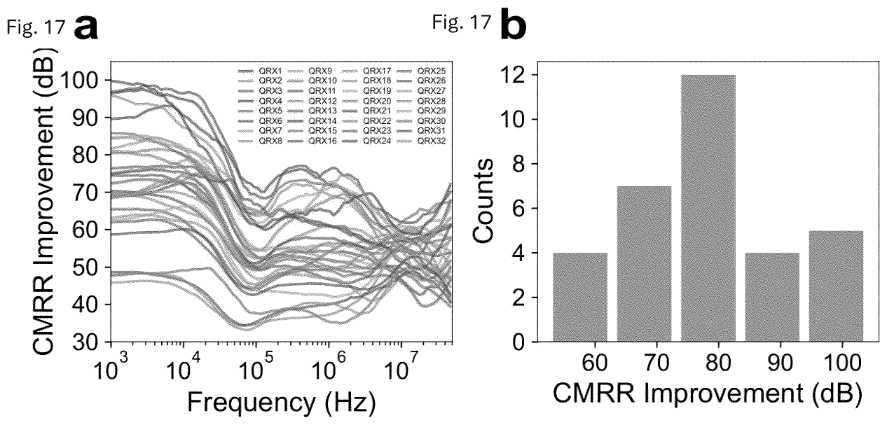

FIG. 16a illustrates a QRX array on a silicon photonics platform [6]. In this embodiment of the disclosed invention, a single-channel QRX is arrayed to make up a 32-channel QRX array.

### 6.1 Single-Channel Silicon Photonic QRX

The single-channel quantum coherent receiver arrayed to make up the array comprises a tunable MachZehnder interferometer (MZI) feeding into a balanced Ge photodiode pair followed by an electronic transimpedance amplifier (TIA). The QRX needs to coherently downconvert and amplify the quantum optical signal while minimizing decoherence with as high timing resolution as possible. This goal introduces several design strategies for QRX design.

### 6.1.1 QRX Design

The performance of a QRX in acquiring quadrature information of a quantum optical state is characterized by its shot noise clearance (SNC), LO power knee (Pₖₙₑₑ), common-mode rejection ratio (CMRR), 3-dB bandwidth (BW_{3 dB}) and shot-noise limited bandwidth (BWₛₕₒₜ) [3, 4]. The noise floor of a QRX can be referred to the input of the electronics (i_{q}) and is, to first order, proportional to

$${i}_{q} ∝ L ( {P}_{L O} + \frac{{P}_{L O} RIN}{CMRR} ) + {i}_{n} \qquad ( 54 )$$

where L signifies the detection loss of the optical receiver, including the quantum efficiency of the photodetectors and optical losses, P_{LO} is the LO power, RIN is the relative intensity noise of the LO, and iₙ is the input-referred current noise density of the electronics. A more convenient expression can be derived by dividing by P_{LO}

$$\frac{{i}_{q}}{{P}_{L O}} ∝ L ( 1 + \frac{RIN}{CMRR} ) + {i}_{n} \qquad ( 55 )$$

The first term of this expression is the signal shot noise, the second term is the noise contribution from LO, and the third term is the noise contribution from the electronics. The common-mode rejection ratio sets the noise contribution from LO compared to signal. Assuming the QRX is operated in the signal shot-noise-limited regime with a high enough CMRR, the output noise power will increase linearly with LO power. At low CMRR, this linear relationship breaks down, introducing decoherence to the downconverted signal [3]. The shot noise clearance is defined as the ratio between the total noise power at the maximum LO power (P_{LO,max}) and the noise power at no LO power, assuming the QRX is operated in the signal shot-noise-limited regime with a high enough CMRR [3].

$$SNC ∝ \frac{L {P}_{LO , max}}{{i}_{n}} \qquad ( 56 )$$

Maximizing the shot noise clearance is crucial to minimize decoherence introduced to the signal. This metric also sets the signal-to-noise ratio (SNR) in the classical operation of the QRX. LO power knee is defined as the LO power required to have 3 dB shot noise clearance (at which the QRX is shot noise limited).

$${P}_{k n e e} ∝ \frac{{i}_{n}}{L} \qquad ( 57 )$$

The Pₖₙₑₑ should be minimized to reduce the QRX power consumption and ensure enough LO power can be supplied to the system as a larger number of QRX is integrated on-chip. The 3-dB bandwidth sets the classical operation bandwidth of a QRX. At the 3-dB cut-off frequency, the QRX output signal will be attenuated by 3 dB. However, in the infinite SNC limit, this 3-dB attenuation would not introduce decoherence to the quantum state and, for classical operation, does not change the SNR. Shot-noise-limited bandwidth is the bandwidth at which the SNC is reduced to 3 dB and at which the QRX stops being shot-noise-limited. This shot-noise-limited cut-off frequency is the frequency above which significant decoherence is introduced to the signal. Therefore, this is the bandwidth used for the quantum operation of the QRX.

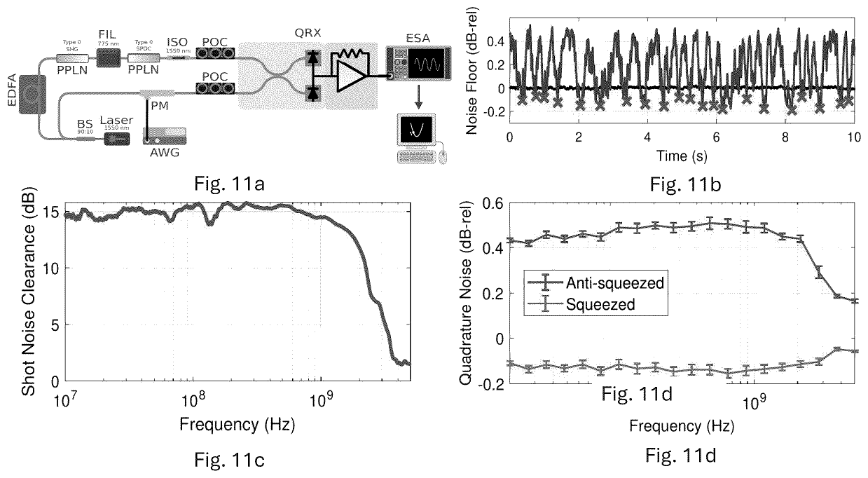

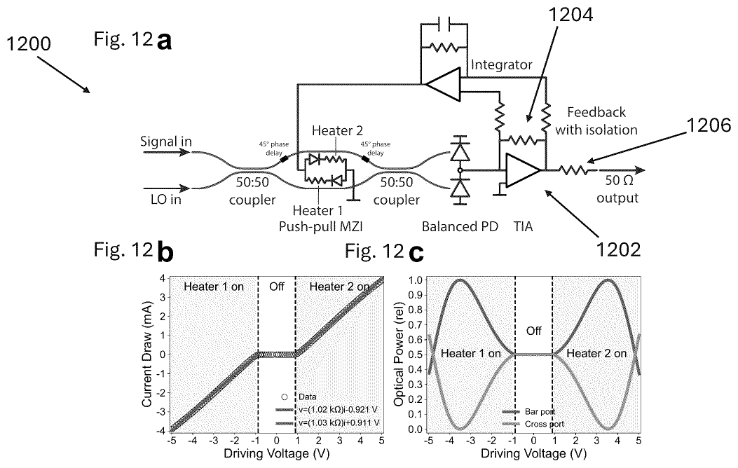

The MZI and balancing of the photodiodes are crucial to ensure high CMRR. In the case of MZI, the tuning range is set by the ideal 50:50 coupling of the directional coupler pair and the maximum relative phase shift that the push-pull thermo-optic phase shifter can introduce to the branches. While in this case, MZI was designed to have a full tuning range (from 0:100 to 100:0 power coupling), a more compact QRX can be realized in future designs by setting the tuning range to be as much as the variance in the imperfections in the 50:50 coupling caused by fabrication variations. The phase shifters in the MZI use resistive heaters made out of doped Si with 1 kΩ resistance in series with 1 V forward voltage Si diodes to enable push-pull configuration. The push-pull configuration allows both positive and negative voltages to be used by turning on/off heaters in the branches. The MZI is designed to provide sufficient tuning with ±5 V drivers. The measured IV characteristic of the push-pull phase shifter from −5 V to 5 V is shown in FIG. 12b. The forward voltages of the diodes in heaters 1 and 2 are 0.921 V and 0.911 V, respectively. The half-wave power of the MZI is measured by tuning the MZI from balanced (50:50) to unbalanced configuration (100:0). The test structure MZI reaches balanced configuration at −2.70 V and unbalanced configuration at 4.20 V. This corresponds to a half-wave power of 18 mW using the measured IV characteristic. Therefore, the optical power splitting for the ideal MZI without fabrication variations can be simulated using the half-wave power and the IV characteristic, as shown in FIG. 12c.

In the design, the photodiodes should also have the same quantum efficiencies and time constants to ensure high CMRR at every frequency. The reverse bias of the photodiodes can be tuned to match their time constants. However, increasing the reverse bias will increase the dark current that could decrease SNC and increase Pₖₙₑₑ. Therefore, both MZI and photodiodes should be holistically designed to ensure maximum CMRR while not compromising other specifications. Finally, the CMRR auto-correction circuitry described herein can be used to realize high-CMRR coherent receivers at scale.

A simplified circuit diagram of the tunable interferometer and the CMRR auto-correction circuit is shown in FIG. 12a.

In addition to CMRR, SNC and Pₖₙₑₑ are set by the dark current of the photodiodes and the electronic noise floor of the electronics. The dark current of the photodiodes can be minimized by lowering the reverse bias, but this introduces a trade-off with bandwidth. Apart from dark current, TIA design is crucial to minimize the input-referred current noise of the electronics. The TIA should provide enough gain to lower the noise contribution of the subsequent electronics and external noise sources, such as EMI, while contributing as minimal noise as possible itself. The noise contribution of the TIA is fundamentally limited by the thermal noise of the resistance determining the transimpedance gain, which scales as iₙ=\sqrt{4 kT/R}, where in is the input-referred current noise spectral density, k is the Boltzmann constant, T is the temperature, and R is the resistance. Therefore, increasing the resistance is crucial to maximize SNC and minimize Pₖₙₑₑ. Since the gain-bandwidth product (fₜ) of the transistors is set by the process technology, this resistance, and consequently electronic noise, has a fundamental trade-off with the bandwidth.

Since sensing and communication applications have different specification requirements from a QRX, two configurations are designed to meet the demands of both. The high bandwidth configuration utilizes a low-gain but high bandwidth TIA to optimize for communications and the high shot noise clearance configuration utilizes a high-gain but low-bandwidth TIA to optimize for sensing.

### 6.1.2 High Bandwidth Configuration

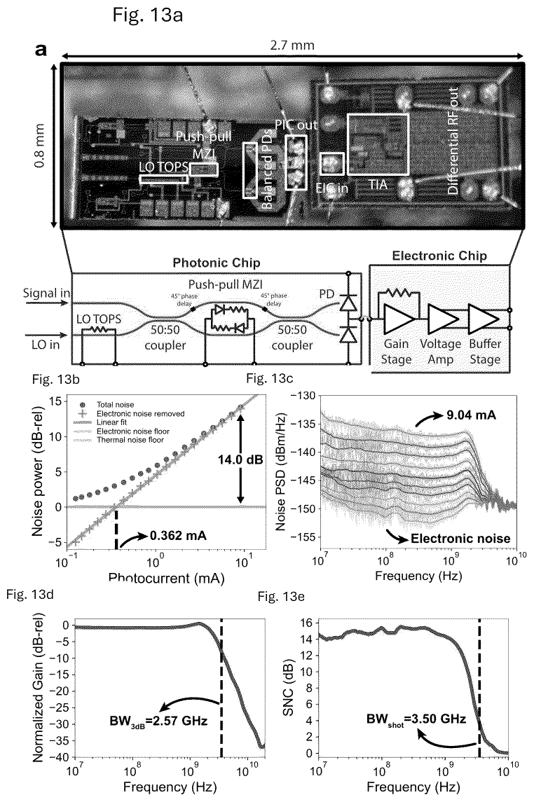

In the high bandwidth configuration, an integrated TIA (ONET4291T) is packaged with a single QRX PIC. The integrated TIA is a three-stage amplifier with two gain stages and a differential output buffer stage. It has a transimpedance gain of 3.2 kΩ and a 3-dB bandwidth of 2.8 GHz. Any parasitics introduced in the path between the photodiodes and the TIA can distort the frequency response of the QRX and reduce bandwidth. Therefore, the bare dies are placed as close as possible with a wirebond less than 200 μm length between the PD output and TIA input. The balanced PDs of the high BW QRX are biased to −1 V to maximize the bandwidth without significantly sacrificing SNC, resulting in a PD bandwidth of >15 GHz. The co-packaged photonic-electronic integrated circuit is mounted on a custom PCB with wirebonds to the chip pads. The differential outputs from the TIA are wirebonded to two 50Ω matched coplanar waveguide transmission lines on the PCB that are routed to two SMA ports. The packaged die photo along with a simplified schematic of the QRX is shown in FIG. 13a.

The high bandwidth QRX was characterized to determine its BW_{3 dB}, BWₛₕₒₜ, SNC, and Pₖₙₑₑ. BW_{3 dB} was characterized by a 20 GHz vector network analyzer (Keysight N5230A). A 1550 nm source (Pure Photonics PPCL700) is modulated by a 40 GHz LiNb modulator (Thorlabs LNA6213) driven by the VNA. S parameters of the modulator are collected with a 40 GHz InGaAs photodiode (Optilab PD40-M-AC) and de-embedded from the final measurement. The differential outputs from the QRX were connected to the VNA, and the S parameters of the output paths are also de-embedded. After calibration, the modulated light is sent to the LO port of the QRX, and the frequency response of the QRX were acquired with a 3-port optoelectronic S-parameter measurement. As seen in FIG. 13d, packaged QRX has an optoelectronic BW_{3 dB} of 2.57 GHz.

SNC and Pₖₙₑₑ characterization was done by sending LO to the LO port of the QRX and sweeping the power. One of the differential outputs was connected to an ESA to measure the noise floor, and the photocurrents from the PDs are monitored with high-precision current meters as the LO power is swept. The ESA was set to a resolution bandwidth of 300 kHz and a video bandwidth of 3 kHz. The measurements were also done in a Faraday cage to minimize RF interference from external sources. The noise spectra of the high BW QRX at different photocurrents are seen in FIG. 13c. A moving average filter was applied to the raw data (transparent lines) to construct the processed data (solid lines). These noise spectra were taken at total photocurrents ranging from 0 mA to 9.04 mA, corresponding to 13.0 mW maximum LO power above which the PDs saturate and distort the spectrum due to nonlinearity from the high amount of photo-excited carriers in the junction. The SNC and Pₖₙₑₑ were extracted from this measurement by integrating the noise spectrum over the operating bandwidth of the QRX. Output noise powers integrated over the QRX bandwidths normalized to the electronic noise power as a function of photocurrent is shown in FIG. 13b.

Electronic noise floor along with the thermal noise floor resulting from 3200Ω are also shown with a difference in noise powers of 0.1 dB, showing that the high BW QRX was operating at the fundamental thermal noise limit. Shot noise powers were also plotted by subtracting the electronic noise powers from the total noise powers, and a linear regression fit is applied to the points above the 3 dB SNC. The gradient from the fit is near unity at 1.009±0.016, confirming the QRX was operating at the signal shot noise limited regime as needed. QRX has an SNC of 14.0 dB over its bandwidth and was shot-noise limited at 0.362 mA photocurrent, corresponding to a Pₖₙₑₑ of 521 μW. BWₛₕₒₜ was characterized by dividing the noise spectrum at maximum LO power by the electronic noise spectrum, resulting in the SNC spectrum shown in FIG. 13e. The SNC drops to 3 dB at 3.50 GHz, setting the bandwidth over which the high bandwidth QRX is shot noise limited. As seen here, the higher bandwidth leads to a lower SNC compared to the lower bandwidth but higher SNC of the high SNC QRX.

### 6.1.3 High Shot Noise Clearance Configuration

In the high SNC configuration, the QRX PIC is packaged with a discrete TIA (LTC6269-10) on a custom PCB. The TIA was a FET-input op-amp with resistive feedback. The op-amp IC has a 4 GHz gain-bandwidth product and is used with a 50 kΩ feedback resistor. The capacitance of the feedback trace was used to ensure sufficient phase margin while keeping the closed-loop gain greater than 10 since the op-amp is decompensated. A 50Ω resistor was placed in series with the output of the TIA for impedance matching and to dampen any oscillations from capacitive loading at the output. The TIA output was routed with 50Ω coplanar waveguide transmission lines to an SMA port. The SMA port was then connected to an RF signal analyzer. The balanced PDs of the high SNC QRX were biased to 0 V to minimize the dark current and the noise coupling through the bias circuit, resulting in a PD bandwidth of >10 GHz.

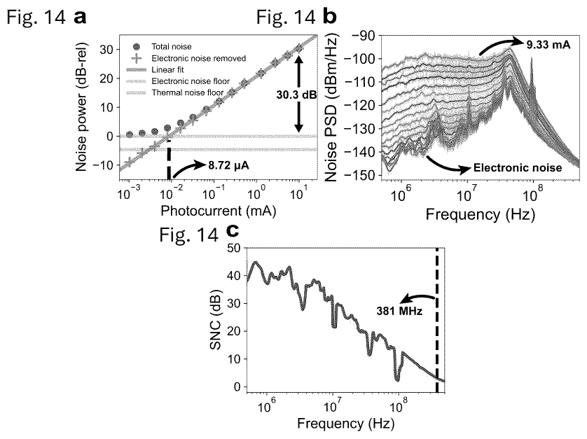

Similar to high BW QRX, SNC and Pₖₙₑₑ characterization was done by sending LO to the LO port of the QRX and sweeping the power. The output was sent to an ESA with a resolution bandwidth of 10 kHz and a video bandwidth of 1 kHz. The noise spectra of the high SNC QRX at different photocurrents are shown in FIG. 14b. A moving average filter was applied to the raw data (transparent lines) to construct the processed data (solid lines). These noise spectra were taken at total photocurrents ranging from 0 mA to 9.33 mA, corresponding to 13.4 mW maximum LO power above which the PDs saturate due to the carrier screening effect. The variation in this saturation current between the two configurations can be attributed to the fabrication variations between the PDs in the two PICs. Since this measurement was not taken in a Faraday cage, there are tones in the spectrum due to EMI from RF transmitters nearby. The tones at 100 MHz are from the broadcast stations on Mount Wilson near Pasadena.

The output noise powers integrated over the QRX bandwidths normalized to the electronic noise power as a function of photocurrent are shown in FIG. 14a. The electronic noise floor along with the thermal noise floor resulting from 50 kΩ are also shown with a difference in noise powers of 4.60 dB. This higher difference can be attributed to external noise such as EMI coupling into QRX. The shot noise powers are also plotted by subtracting the electronic noise powers from the total noise powers, and a linear regression fit is applied to the points above the 3 dB SNC. The gradient from the fit is near unity at 1.004±0.006, confirming the QRX was operating at the signal shot noise limited regime. The QRX has an SNC of 30.3 dB over its bandwidth and is shot-noise limited at 8.72 μA photocurrent, corresponding to a Pₖₙₑₑ of 12.5 μW. BWₛₕₒₜ is characterized by dividing the noise spectrum at maximum LO power by the electronic noise spectrum, resulting in the SNC spectrum shown in FIG. 13c. The SNC drops below 3 dB before the QRX hits BWₛₕₒₜ at 89.8 MHz due to the EMI from Mount Wilson FM transmitters. The SNC rises again and drops back to 3 dB at a BWₛₕₒₜ of 381 MHz.

### 6.1.4 Common-Mode Rejection Ratio Characterization

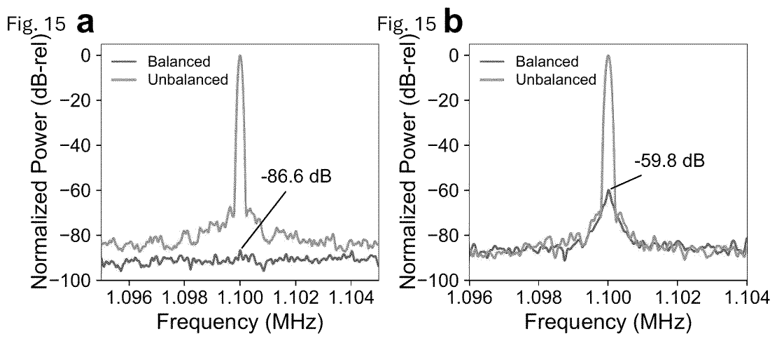

Since the CMRR is set by the QRX PIC, both high BW and high SNC configurations have the same CMRR. CMRR was measured by setting the push-pull MZI in the PIC to unbalanced (100:0) and balanced (50:50) settings while injecting intensity-modulated LO to the QRX. A 1550 nm source (APEX AP3350A) was intensity modulated at 1.1 MHz, and the modulated light was sent to the LO port of the QRX. The QRX output was connected to an RF signal analyzer to measure the RF power at 1.1 MHz. Two measurements were taken by tuning the MZI to unbalanced and balanced settings. The CMRR was then calculated as

$$CMRR = 10 {log}_{10} ( \frac{{P}_{unb}}{4 {P}_{bal}} ) \qquad ( 58 )$$

where P_{unb} and P_{bal} are the unbalanced and balanced RF power measurements, respectively. The CMRR measurements were taken with the signal analyzer using a frequency span of 10 kHz, resolution and video bandwidths of 100 Hz, and a center frequency of 1.1 MHz. To validate the stability of CMRR, ten snapshots were taken over the course of 10 seconds for both balanced and unbalanced settings. The CMRR was then calculated from the average of the traces in these snapshots. In the initial measurement, due to the limited dynamic range of the ESA, the balanced measurement was able to suppress the 1.1 MHz peak below the noise floor as seen in FIG. 15a. The average CMRR from 10 traces measured over 10 seconds from this initial measurement was 80.6 dB. To increase the dynamic range and resolve the suppressed peak, the LO power in balanced measurement was increased by 18 dB. The LO power difference between balanced and unbalanced measurements was monitored and recorded throughout the measurements with an average power difference of 18.2 dB. The resulting traces after changing the LO power in the balanced measurement are shown in FIG. 15b. The average CMRR from 10 traces measured over 10 seconds from this final measurement is 90.2 dB, with a maximum CMRR of 92.3 dB. This CMRR was measured for only a single frequency of 1.1 MHz but can be repeated for other frequencies to measure the CMRR response as well as shown in Sec. 6.3.

### 6.1.5 Loss Characterization

Optical insertion loss of QRX PIC was characterized by sending power to the LO port and measuring the total photocurrent from the PDs. For 136 μW input power, the measured photocurrent was 44.0 μA, corresponding to 4.88 dB loss. The standard grating coupler that couples LO power into QRX had 3.30 dB loss. De-embedding this loss, QRX had an optical insertion loss of 1.58 dB. PDs have a quantum efficiency of 70.4%, corresponding to 1.52 dB loss. Waveguide propagation loss for the LO through 300 μm path in the single QRX test structure was 0.0599 dB from 2 dB/cm measured path loss with negligible excess loss from the phase shifter and couplers in the MZI. This led to an expected optical insertion loss of 1.58 dB that matches well with the measurement. In addition to optical insertion loss, SNC also contributes as an effective loss to the quantum state since noise other than quantum noise acts as uncorrelated noise in the system. This effective loss can be calculated by η_{SNC}=1−10^{-SNC}/10. For high BW QRX, 14.0 dB SNC corresponds to 0.176 dB loss, and for high SNC QRX, 30.3 dB SNC corresponds to 0.00405 dB loss. Hence, high BW QRX had a total characterized loss of 1.69 dB, and high SNC QRX has a total characterized loss of 1.52 dB.

### 6.2 Silicon Photonic QRX Array

After component characterization, the QRX array PIC was packaged with electronics (high SNC configuration) on an RF motherboard. The pictures of the packaged system are shown in FIG. 16.

The QRX array chip was first packaged with an interposer board for fanning the electronic input/output (IO) to/from the chip. The interposer board was designed with a laser-milled cavity in the middle to place the QPA chip surrounded by pads with blind vias for high-density routing. The chip and the interposer were assembled so that the on-chip pads were level and parallel with the on-board pads to shorten the bond wire length. The traces from the interposer pads to the TIA inputs on the motherboard were minimized and spaced sufficiently apart to minimize electronic crosstalk with 500 coplanar waveguide (CPW) transmission lines. The discrete TIA circuit on the motherboard utilized a FET-input operational amplifier (op-amp) with resistive feedback. The op-amp IC (LTC6269-10) had a 4 GHz gain-bandwidth product and was used with a 50 kΩ feedback resistor. The capacitance of the feedback trace was used to ensure sufficient phase margin while keeping the closed-loop gain greater than 10 since the op-amp is decompensated. A 50Ω resistor was placed in series with the output of the TIA for impedance matching and to dampen any oscillations from capacitive loading at the output. The TIA outputs were routed with 50 ΩCPW transmission lines to a high-speed, high-density connector to route the signals to data acquisition.

The DC voltage across the TIA feedback resistor was used as the error signal for the CMRR correction and drives an integrator circuit with a chopper-stabilized op-amp IC (OPA2187) for low voltage offset, flicker noise, and offset drift. The integrator unity-gain bandwidth was set close to DC to dampen any oscillations in the CMRR auto-correction feedback. The integrator's output was fed back to the MZI on the QPA chip to correct the CMRR continuously. The polarity of the integrator was designed to match the polarity of the push-pull MZI so that the correction circuit always maximizes the CMRR, whether the imperfections lead to negative or positive DC current from the balanced photodiodes. The correction was limited by the dark current of each QRX and the offset voltage at the input of each integrator, but offset correction can be applied to each integrator to further maximize the CMRR.

The CMRR auto-correction circuit extracts an error signal from the TIA output, probing the imperfect CMRR of each QRX and feeding it back to each respective push-pull MZI to continuously correct the CMRR of the QRX array. This ensures shot-noise-limited noise floor during chip measurements, maximizing the shot noise clearance and effective efficiency. A high-speed coaxial cable assembly was used to connect to the high-density connector on the motherboard. The cable first connects to a power board, powering the active electronics on the motherboard. This board also routes the output from the two photodiodes connected to the two edge antennas of the aperture and the output from the monitor photodiode connected to the LO coupler to current meters for continuous monitoring of signal and LO alignment on the chip. Another cable then connects the remaining IO to a splitter board that splits the 32 QRX outputs for simultaneous imaging and RF data acquisition. The remaining control lines for tuning the on-chip TOPS are connected to 32 digital-to-analog converters (DACs) for independent phase tuning of each QRX.

Scaling quantum systems is a non-trivial and challenging task that serves as the bottleneck for many quantum technologies. The QRX array was characterized to show it can operate at scale with a high number of parallelized channels with minimal crosstalk, parasitics and noise as the system is scaled. A key benchmark for this was to confirm all of the QRX channels are working in the signal shot-noise-limited regime with high CMRR and SNC. Therefore, all of the 32 QRX channels were characterized to find their CMRR and SNC.

### 6.3 32-Channel Common-Mode Rejection Ratio (CMRR)

CMRR auto-correction described in Sec. 6.1 allows the QRX array to work at scale with quantum limited sensitivity and protects the system from fabrication variations as the QRX channels are arrayed. The increase in CMRR in all channels between when the CMRR auto-correction is turned off and on was characterized by sending an intensity modulated LO into the QRX array PIC. 32 channel outputs were connected to 32 digitizers with 100 MHz bandwidth and 100 MSa/s sampling rate. 10 ms traces were recorded with CMRR auto-correction turned off and on. The amplitude modulation frequency was swept from 1 kHz to 50 MHz to characterize the CMRR increase of all 32 channels with CMRR auto-correction at every operating frequency. These traces were then converted into frequency domain, and the peak amplitudes at the modulation frequencies were recorded. The change in amplitude between when the CMRR auto-correction is turned off and when it is turned on characterizes the improvement in CMRR for each channel with CMRR auto-correction. While this doesn't directly characterize CMRR, it gives a lower bound on the CMRR of each QRX. The resulting improvements in CMRR over frequency are shown in FIG. 17a. To characterize the variation in CMRR across channels, the maximum CMRR improvement for each trace was recorded and plotted in a histogram in FIG. 17b. The median CMRR improvement is 76.8 dB. with a minimum of 52.4 dB and a maximum of 104.2 dB.

### 6.4 32-Channel Shot Noise Clearance (SNC)

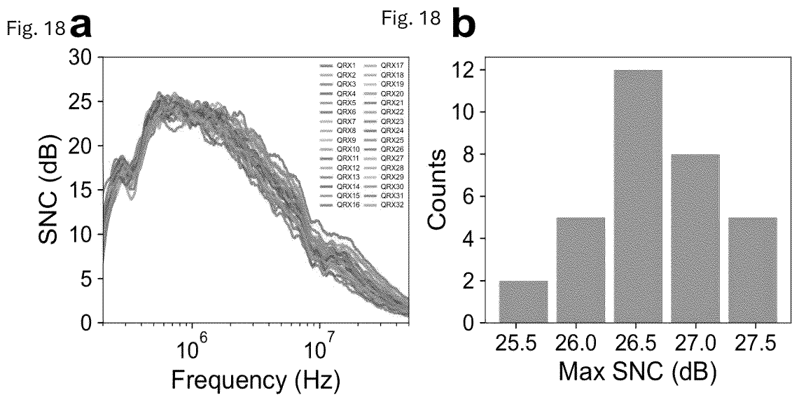

High SNC QRX design enables arrayed coherent receivers with quantum-limited sensitivity at scale. Due to its low Pₖₙₑₑ, a large number of channels can be parallelized operating at the signal shot noise limited regime without hitting a bottleneck in available LO power. In addition to reducing power consumption, the 12.5 μWPₖₙₑₑ allows thousands of QRX channels to be parallelized with a single LO optical input before hitting the two-photon absorption power ceiling in Si waveguides. To confirm high SNC operation of QRX at scale, SNCs of all 32 channels were recorded with the ESA. Similar to the SNC characterization in Sec. 6.1, noise spectra of the channels were acquired with the QRX array PIC being injected with maximum LO power before the onset of PD breakdown in one of the QRX channels. The same noise spectra were also acquired without any LO power to measure the electronic noise floor. The ratio between the two noise spectra gives the SNC frequency response. Measured SNC frequency responses of all 32 QRXs are shown in FIG. 18a. As seen here, all channels operate well into the signal shot noise limited regime. To characterize the variation in SNC across QRXs, the maximum SNC over the spectrum without integrating over bandwidth was recorded for each QRX and plotted in a histogram as shown in FIG. 18b. The maximum SNC variation is low, with a minimum of 25.3 dB and a maximum of 27.7 dB. The median SNC is 26.6 dB.

### 7. Communication System

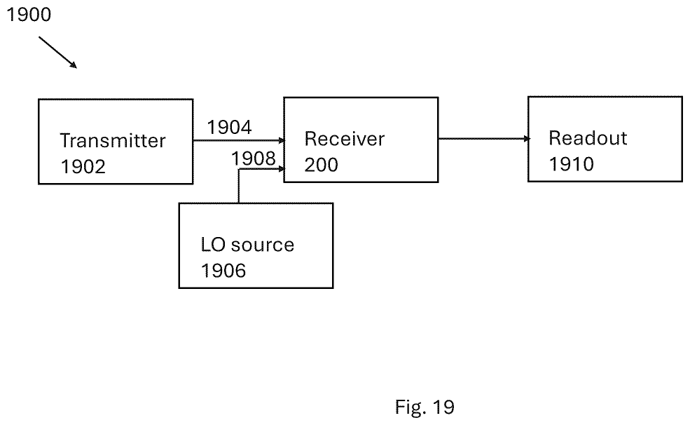

FIG. 19 illustrates a communication system 1900 comprising the receiver 200, 600, 700, according to embodiments described herein; a transmitter 1902 (e.g., comprising a laser and/or laser pumped nonlinear medium comprising an SPDC source) for transmitting first electromagnetic radiation 1904 comprising the quantum signal encoded with information using one or more degrees of freedom in a phase space representing a quantum state of the quantum signal; an LO source 1906 for transmitting second electromagnetic radiation 1908 comprising the LO signal; and a readout circuit 1910 for decoding the information from the degrees of freedom carried by the electrical signal outputted from the electronic integrated circuit.

### Sensor System

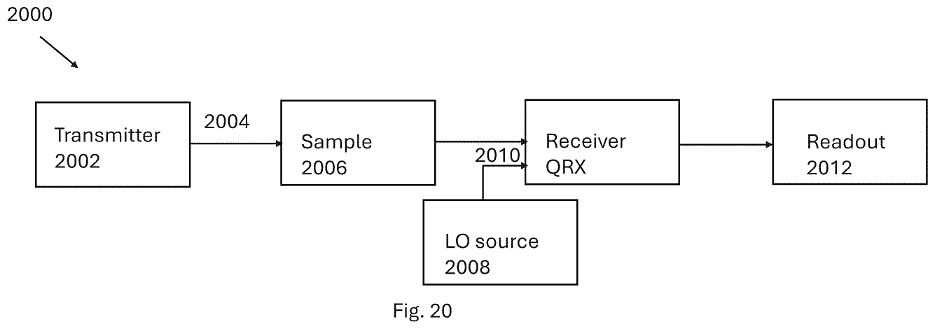

FIG. 20 illustrates a sensor system 2000 comprising the receiver according to embodiments described herein, further comprising a transmitter 2002 (e.g., comprising a laser and/or laser pumped nonlinear medium comprising an SPDC source) for transmitting first electromagnetic radiation 2004 comprising the quantum signal to a sample 2006, wherein the signal input of the receiver is positioned to receive the first electromagnetic radiation reflected from or transmitted through the sample 2006; an LO source 2008 for transmitting second electromagnetic radiation 2010 comprising the LO signal; and a readout circuit 2012 for determining information about the sample from one or more degrees of freedom in a phase space representing a quantum state of the quantum signal and carried in the electrical signal outputted from the electronic integrated circuit.

### Quantum Information Processing System

In one or more embodiments, the receiver is coupled to a radio-frequency or microwave circuit U_{RF} after photodetection, wherein the RF or microwave circuit can implement arbitrary matrix multiplication for quantum information processing.

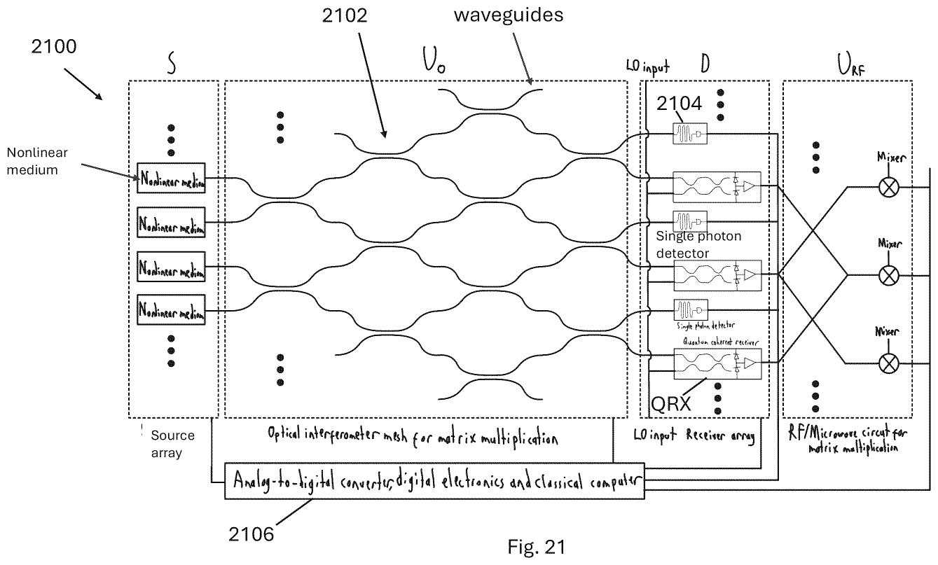

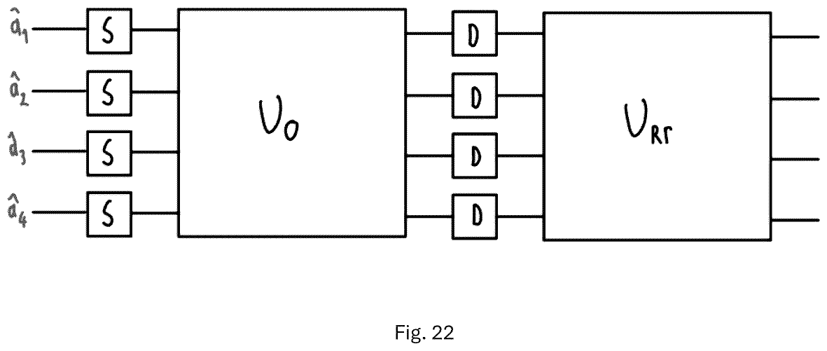

FIG. 21 and FIG. 22 illustrate a computing system 2100 comprising a detection system D comprising the receiver QRX according to one or more embodiments, further comprising an array of sources S (e.g., each comprising a nonlinear medium) that can generate squeezed states or photon number states; an optical interferometer mesh U_{O} (comprising interferometers 2102) and a co-designed radio-frequency or microwave circuit U_{RF} that can implement arbitrary matrix multiplications to the quantum signals in the photonic or electronic domain while maintaining coherence during optoelectronic downconversion; one or more single photon detectors 2104 connected to some outputs of the optical interferometer mesh for heralding to implement non-Gaussian operations; and a central classical computer 2106 interfaced with the photonic and electronic quantum circuits that can implement a universal gate set suitable for universal quantum computing.

In one or more embodiments, the RF circuit and the optical interferometer mesh are co-designed so that each side (optical or RF) can be accordingly designed or reconfigured taking into account what matrices are being multiplied on the other side (optical or RF). The photonic circuit (interferometer mesh) and the electronic circuit can be designed taking advantage of the coherence being maintained through optical-to-RF downconversion in the receivers and implementing the matrix multiplication operations accordingly in a dynamic way (RF circuit implements a matrix based on what the optical mesh implements and vice versa).

### Process Steps

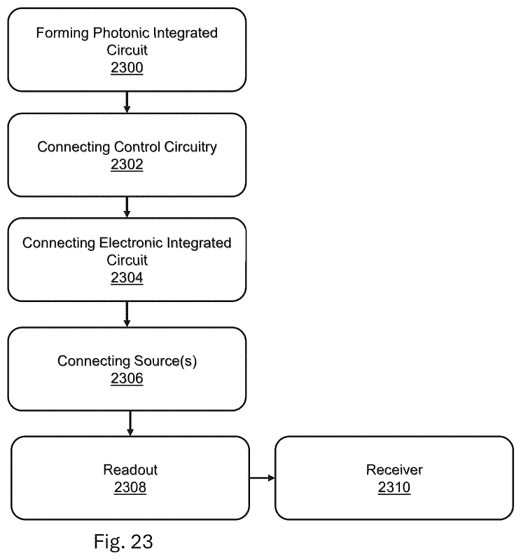

FIG. 23 illustrates a method of making a receiver, comprising the following steps (see Block 2300 represents fabricating a photonic integrated circuit on a substrate, the circuit comprising:
a signal input for receiving an arbitrary quantum signal;
an LO input for receiving a local oscillator signal;
one or more couplers comprising coupled waveguides for interfering the quantum signal and the LO signal, the couplers comprising a first input connected to the signal input and a second coupler input connected to the LO input; a first output; and a second output, wherein the first output outputs a first interference signal and the second output outputs a second interference signal in response to the quantum signal and the LO signal; an
one or more phase shifters coupled to the couplers; and
a pair of photodetectors comprising a pair of photodetectors comprising a first photodetector connected to the first output and a second photodetector connected to the second output; wherein first photodetector and the second photodetector are connected in series and the pair comprises a detector output between the photodetectors and the photodetectors outputting a difference signal between a first output signal (from the first photodetector in response to the first interference signal) and a second output signal (from the second photodetector in response to the second interference signal) such that the output signals cancel each other when they are equal and at least one quadrature component of the quantum signal can be determined from the difference signal.

In one or more embodiments, the signal input and the LO input comprise a grating, an antenna, or a waveguide for receiving a coupled signal, the waveguides comprise silicon, silicon nitride, indium phosphide or lithium niobate on an oxide acting as a cladding, and the phase shifters comprise metallization for biasing the waveguides or resistive material (e.g., titanium nitride) for resistors in series with a diode for heating the waveguides.

Block 2302 represents optionally connecting integrating one or more control circuits with the photonic integrated circuit for controlling CMRR, Pknee, and shot noise clearance of the receiver as a function of a desired operation bandwidth or optical bandwidth used for determining a degree of freedom including a quadrature component, or a variance of the quadrature component of the quantum signal in a quantum sensing or quantum communication or computation application.

Block 2304 represents connecting the photonic integrated circuit to an electronic integrated circuit comprising an amplifier (e.g., comprising CMOS transistors) for amplifying the difference signal to form and electrical signal and a readout circuit for reading out the quadrature component from the electrical signal.

Block 2306 represents optionally connecting the source of the LO signal and/or the source of the quantum signal, In one embodiment, the sources each comprise a nonlinear waveguide phase matched and dispersion engineered for emitting photons comprising the quantum signal or a coherent state (in the case of the LO signal) using an SPDC process. In one more embodiments, the LO source comprises a tunable source for emitting a range of wavelengths.

Block 2308 represents optionally connecting a readout circuit. In one or more embodiments, the readout circuit can comprise a general type of circuit since analog processing can be performed on the signals during readout. The final stage of readout can be an analog-to-digital converter (ADC) after which the data can be sent to a computer for digital signal processing.

In one or more embodiments, one or more of the photonic integrated circuit, the control circuits, the electronic integrated circuits, and the readout circuits can be fabricated and/or integrated using lithographic processes [7].

Block 2310 represents the end result, a device or system comprising a receiver. The device can be embodied in many ways including, but not limited to, the following (referring also to FIGS. 1-18)

1. A receiver 200, comprising:
a signal input 202 for receiving an arbitrary quantum signal;
an LO input 204 for receiving a local oscillator (LO) signal;
one or more couplers 206 for (e.g., but not limited to, configured for, adapted to/for, operable to/for, capable of) interfering and/or mixing the quantum signal and the LO signal, the couplers comprising a first input 208 connected to the signal input and a second input 210 connected to the LO input; a first output 212; and a second output 214, wherein the first output outputs a first interference/mixing signal and the second output outputs a second/mixing interference signal in response to the interference/mixing of the quantum signal and the LO signal;
a pair of photodetectors 216 comprising a first photodetector PD_{β} connected to the first output and a second photodetector PD_{α} connected to the second output; wherein first photodetector (comprising first detector output 216) and the second photodetector (comprising second detector output 218) are connected in series and the pair comprises a detector output 220 between the photodetectors and the photodetectors outputting a difference signal between a first output signal (from the first photodetector in response to the first interference signal) and a second output signal (from the second photodetector in response to the second interference signal) such that the output signals cancel each other when they are equal and at least one quadrature component of the quantum signal can be determined from the difference signal.

2. The receiver of clause 1, further comprising a trans-impedance amplifier 222 coupled to the detector output.

3 The receiver of clause 1 or 2, further comprising one or more phase shifters 702 coupled to the couplers.

4. The receiver of any of the clauses 1-3, further comprising an error correction circuit 704 connected to at least one of the phase shifters, wherein the error correction circuit outputs a feedback signal to the at least one phase shifter controlling a coupling ratio of at least one of the couplers in response to the difference signal, wherein the coupling ratio reduces common-mode noise (or increases common mode rejection ratio) at the detector output.

5. The receiver of clause 4, wherein the error correction circuit comprises an integrator 602 configured to measure a DC component of the difference signal in a presence of the LO signal only and outputting the feedback signal to the at least one phase shifter that cancels or minimizes the DC component.

6. The receiver of any of the clauses 1-5, wherein at least one of the phase shifters is configurable to tune one or more of the couplers for 50:50 coupling.

7. The receiver of any of the clauses 1-6, further comprising a Mach Zehnder Interferometer 604, e.g., comprising two of the couplers 606a, 606b connected in series.

8. The receiver of clause 7, wherein:
the Mach Zehnder Interferometer comprises a push-pull interferometer comprising a first arm 608 outputting to the first output 212 of the couplers and a second arm 610 outputting the second output 214 of the couplers;
the first arm is coupled to a first phase shifter 612; and
the second arm is coupled to a second phase shifter 614 configured to be off when the first phase shifter is on and on when the first phase shifter is off.

9. The receiver of clause 8, wherein the first phase shifter comprises a first diode and the second phase shifter comprises a second diode 616 reverse biased compared to the first diode.

10. The receiver of clause 9, wherein the phase shifters comprise heaters 618 for controlling a refractive index of the arms (and thereby a phase of the signal in each of the arms) through a thermal optical effect.

11. The receiver of any of the clauses 1-10, further comprising a biasing circuit 706 coupled to the photodetectors for independently tuning at least one of a dark current and the response of each of the photodetectors to set a shot noise clearance of the receiver in a predetermined range.

12. The receiver of any of the clauses 1-11, comprising a photonic integrated circuit 800, 1000 comprising the first input, the second input, the couplers, and the photodetectors, wherein the couplers comprises coupled waveguides.

13. The receiver of clause 12 further comprising a first substrate 1002 comprising the photonic integrated circuit and a second substrate 1004 comprising an electronic integrated circuit 1006 comprising a trans-impedance amplifier TIA electrically connected to the detector output.

14. The receiver of clause 12 or 13, wherein the electronic integrated circuit further comprises:
a voltage amplifier 1008 connected to an output of the trans-impedance amplifier; and
a buffer amplifier 1010 connected to an output of the voltage amplifier, wherein the buffer amplifier has a buffer output with an impedance for connection to a readout circuit 1012 for determining an amplitude and time dependence of the quadrature component from an electrical signal outputted from the buffer amplifier in response to the output signals received from the detector output.

15. The receiver of claim 12 or 13, wherein:
the trans-impedance amplifier (TIA) is a FET-input op-amp 1200 with resistive feedback comprising an at least 50 kΩ feedback resistor 1202 for >30 dB shot noise clearance
the electronic integrated circuit further comprises a 500 resistor 1204 connected in series with the output of the TIA for impedance matching and having an output for direct connection to a readout circuit for measuring the electrical signal outputted from the TIA in response to the output signals received from the detector output in a sensing application.

16. The receiver of any of the clauses 12-15, wherein:
the photonic integrated circuit further comprises one or more control circuits 704, 706 coupled to at least one of the couplers for controlling a coupling ratio of the couplers, the photodiodes/photodetectors 216 for controlling a dark current and the response of the photodiodes/photodetectors, or an LO power or phase of the LO signal, and
the electronic integrated circuit comprises a gain and output impedance;
such that the receiver:
is shot noise limited and has a shot noise clearance of at least 30 dB, and a Pknee of at most 10 microwatts; or
has 3-dB bandwidth of at least 2 GHz, a shotnoise limited bandwidth of at least 3.5 GHz, a shot noise clearance of at least 10 dB, and a Pknee of at most 500 microwatts.

17. The receiver of any of the clauses 12-16, wherein:
the photonic integrated circuit further comprises one or more control circuits 704, 706 coupled to at least one of the couplers for controlling a coupling ratio of the couplers, the photodiodes for controlling a dark current and response of the photodiodes, or an LO power or phase of the LO signal, and
the electronic integrated circuit comprises a gain and output impedance such that:
a readout circuit 1012 coupled to the output of the electronic integrated circuit can decode one of a plurality of spatiotemporal modes of the quantum signal or a variance of the quadrature component from an electrical signal outputted from the electronic integrated circuit in response the output signals outputted at the detector output.

18. The receiver of any of the clauses 1-17, further comprising a phase locking circuit 902 for phase locking the electrical signal to any of the quadrature components of the quantum signal so that an amplitude of the quadrature component can be measured with sub-shot noise level precision or with quantum noise limited precision.

19. The receiver of any of the clauses 1-18, further comprising an array of the receivers 1602 wherein:
an array of the photonic integrated circuits 1602 are coupled to the electronic integrated circuit 1604 on a motherboard 1606 via an interposer 1608; and
each of the receivers comprises a different channel in a communication system.

20 The receiver of any of the clauses 1-19, further comprising a radio-frequency or microwave circuit connected to the detector output after photodetection and that can or is configured to implement arbitrary matrix multiplication for quantum information processing.

21. The receiver of any of the clauses 12-20, wherein the control circuits and/or the photonic integrated circuits and/or the electronic integrated circuit are configured to operate with at most 5V drive voltage and a coupling ratio of the couplers is 50:50 coupling or tunable to correct for changes in the coupling ratio caused by fabrication imperfections.

23. A computing system 2100 comprising the receiver QRX of any of the clauses 1-21, further comprising:
an array of sources S that can generate squeezed states or photon number states;
an optical interferometer mesh U_{O} connected to the signal input and a co-designed radio-frequency or microwave circuit U_{RF} connected to the detector output and that can implement arbitrary matrix multiplications to the quantum signals in the photonic or electronic domain while maintaining coherence during optoelectronic downconversion;
one or more single photon detectors 2104 connected to some outputs of the optical interferometer mesh for heralding to implement non-Gaussian operations; and
a central classical computer 2106 interfaced with the photonic and electronic quantum circuits that can implement a universal gate set suitable for universal quantum computing.

24. A communication system 1900 comprising the receiver QRX of any of the clauses 1-21, further comprising:
a transmitter 1902 for transmitting first electromagnetic radiation 1904 comprising the quantum signal encoded with information using one or more degrees of freedom in a phase space representing a quantum state of the quantum signal;
an LO source 1906 for transmitting second electromagnetic radiation comprising the LO signal; and
a readout circuit 1910 for decoding the information from the degrees of freedom carried by the electrical signal outputted from the electronic integrated circuit.

25. A sensor system 2000 comprising the receiver QRX of any of the clauses 1-21, further comprising:
a transmitter 2002 for transmitting first electromagnetic radiation 2004 comprising the quantum signal to a sample 2006, wherein the signal input of the receiver is positioned to receive the first electromagnetic radiation reflected from or transmitted through the sample;
an LO source 2008 for transmitting second electromagnetic radiation comprising the LO signal; and
a readout circuit 2012 for determining information about the sample from one or more degrees of freedom in a phase space representing a quantum state of the quantum signal and carried in the electrical signal outputted from the electronic integrated circuit.

26. The sensor system or communication system or computing system of clauses 23, 24, or 25 wherein the phase space is represented using two orthogonal quadratures and the degrees of freedom include a shape of the phase space or a variance of at least one of the two quadratures characterized by the Heisenberg uncertainty principle ΔxΔp≥ℏ/2 so that the information is encoded in the quantum signal by manipulating single photon statistics of the first electromagnetic radiation and/or preparing and measuring the quadrature component of the quantum signal with a variance below the constant variance associated with a classical coherent state and/or wherein the quantum noise of the quadrature component is below the shot noise limit.

27. The receiver of any of the clauses 1-21, wherein:
the quantum signal is prepared in a non classical quantum state (e.g., characterized by sub poissonian statistics wherein an average number of photons in a photodetection of the signal shows a standard deviation that is less than the mean number of the photons and the LO signal comprises a classical coherent state; and
the receiver is configured such that the electrical signal has a noise level that enables measurement of the quadrature component having the reduced variance associated with the sub-Possonian statistics, or
the receiver is configured such that the electrical signal has the noise level that enables measurement of the quadrature component having a quantum noise less than the shot noise limit.

28. The receiver of any of the clauses 1-21, wherein:
the quantum signal is prepared in a squeezed state of light exhibiting reduced noise or variance in one quadrature component and the electrical signal has the noise level that enables measurement of the quadrature component having the reduced noise or variance, or
the quantum signal is prepared in a Fock state or photon number state.

29. A method of making a receiver, comprising:
fabricating a photonic integrated circuit on a substrate, the circuit comprising:
a signal input for receiving an arbitrary quantum signal;
an LO input for receiving a local oscillator signal;
one or more couplers comprising coupled waveguides for interfering the quantum signal and the LO signal, the couplers comprising a first input connected to the signal input and a second coupler input connected to the LO input; a first output; and a second output, wherein the first output outputs a first interference signal and the second output outputs a second interference signal in response to the quantum signal and the LO signal; an
one or more phase shifters coupled to the couplers; and
a pair of photodetectors comprising a pair of photodetectors comprising a first photodetector connected to the first output and a second photodetector connected to the second output; wherein first photodetector and the second photodetector are connected in series and the pair comprises a detector output between the photodetectors and the photodetectors outputting a difference signal between a first output signal (from the first photodetector in response to the first interference signal) and a second output signal (from the second photodetector in response to the second interference signal) such that the output signals cancel each other when they are equal and at least one quadrature component of the quantum signal can be determined from the difference signal.

30 The method of clause 29, further comprising connecting the photonic integrated circuit to an electronic integrated circuit comprising an amplifier (e.g., comprising CMOS transistors) for amplifying the difference signal to form and electrical signal and a readout circuit for reading out the quadrature component from the electrical signal.

31. The method of clause 29 or 30, wherein the signal input and the LO input comprise a grating, an antenna, or a waveguide for receiving a coupled signal, the waveguides comprise silicon, silicon nitride, indium phosphide or lithium niobate on an oxide acting as a cladding, and the phase shifters comprise metallization for biasing the waveguides or resistive material (e.g., titanium nitride) for resistors in series with a diode for heating the waveguides.

32. The method of any of the clauses 29-31, further comprising integrating one or more control circuits with the photonic integrated circuit for controlling CMRR, Pknee, and shot noise clearance of the receiver as a function of a desired operation bandwidth or optical bandwidth used for determining a degree of freedom including a quadrature component, or a variance of the quadrature component of the quantum signal in a quantum sensing or quantum communication or computation application and optionally determining the CMRR, Pₖₙₑₑ, and shot noise clearance needed for a desired application of the receiver.

33 The method of any of the clauses 29-32, further comprising connecting the source of the LO signal and the source of the quantum signal, wherein the sources each comprise a nonlinear waveguide phase matched and dispersion engineered for emitting photons comprising the quantum signal or a coherent state (in the case of the LO signal) using an SPDC process.

34. The method or device of any of the clauses 1-33, wherein the LO source comprises a tunable source for emitting a range of wavelengths.

35. A method of sensing or receiving information encoded in a quantum signal comprising detecting one or more degrees of freedom of the quadrature component of the quantum signal using the receiver of any of the clauses 1-28.

36. The method of clause 35, wherein the degrees of freedom comprise a phase, amplitude, or variance of the quadrature component.

37. A receiver for a quantum signal, comprising:
means for mixing or interfering (e.g., a mixer for mixing or interferometer or coupler for interfering, or a mixer or interferometer or coupler configured for, adapted to/for, operable to/for, or capable of mixing or interfering) a local oscillator signal and a quantum signal to form interference signals; and
means for detecting (e.g., a pair of photodetectors that can be balanced, configured, or adapted, for outputting a difference signal in response to) the interference signals; and
an amplifier (e.g., trans impedance amplifier, or operational amplifier) or one or more amplifiers or means for amplifying (e.g., electronic circuit for amplifying the difference signals and determining a quadrature component of the quantum signal from the difference signals with shot noise limited precision or sub-shot noise limited precision.

38. The receiver of clause 37, wherein quantum noise of the quadrature component is below the shot noise limit of the receiver.

39. The receiver of clause 37 or 38 further comprising the components of any of the clauses 2-28.

40. The receiver of any of the clauses 1-28 or 37 manufactured using the method of any of the clauses 29-34 and optionally manufactured using lithographic patterning.

41. The method of any of the clauses 35-36 utilizing the receiver of any of the clauses 1-18 or 37.

42. The device or method of any of the clauses 1-41, wherein the electromagnetic radiation of the quantum signal and/or the LO comprises an electromagnetic wave, e.g., having one or more wavelengths, e.g., in a range of 400 nm to 10 micrometers, or pulses of electromagnetic radiation e.g., having full width at half maximum/duration less than 1 nanosecond or in a range of 3 femtoseconds-1 nanosecond, or other wavelengths corresponding to optical, visible, or infrared ranges useful for telecom, communications, sensing, quantum computing, or other photonics applications.

43. The device or method of any of the clauses 1-42, wherein at least one of the LO source or the quantum signal source comprise a laser, a light emitting diode (LED), a light emitting device (e.g., laser or LED comprising a semiconductor device), a fiber, an optical parametric amplifier or optical parametric generator or optical parametric oscillator, or nonlinear medium using a nonlinear (e.g., second order chi(2) or χ(2) process) to generate signal and/or idler pulses or waves in response to a pump wave or pulse incident on the nonlinear medium (wherein the nonlinear medium can be pumped by a laser outputting the pump for example). In one or more examples, the nonlinear medium is a (e.g., thin film) waveguide quasi phase matched (e.g. by periodic poling) and dispersion engineered for the parametric process generating the signal and/or idler from the pump (e.g., but not limited to, spontaneous parametric down conversion (SPDC)). Example nonlinear media include, but are not limited to lithium niobate, lithium niobate thin film on substrates including, but not limited to, silicon dioxide on silicon, silicon dioxide on bulk lithium niobate, quartz and sapphire. Other nonlinear materials (e.g., having second order nonlinearity) can be used, however, including doped and un-doped variants of lithium niobate (LN) and lithium tantalate (LT), as well as graphene and III-V materials such as AlN, AlGaN, GaN, GaPN, InGaN, InPN, InN, AlP, AlGaP, AlInP, GaP, AlAs, GalnP, GaAs, InP, InGaP, AlSb, GaSb, InSb, InAs, and various phase matching schemes including quasi-phase matching, birefringent phase matching, and modal phase matching can be considered.

44. The device or method of any of the clauses 1-43, wherein at least one of the LO source or the quantum signal source comprise an array of sources.

45 The device or method of any of the clauses 1-44, wherein the readout circuit comprises an analog-to-digital converter (ADC) (after which the data can be sent to a computer for digital signal processing) and optionally one or more processors for processing the digital signals outputted from the ADC.

46. The device of any of the clauses 1-45, wherein the quantum signal comprises a quantum level signal comprising at least one of a qubit, a signal having a small amplitude (e.g., single photon level), a single photon signal, a signal in a quantum state, or a signal in a superposition of quantum states, or an entangled state, a squeezed state, a non-classical state, or a Fock state.

47. The device of any of the clauses 1-46, wherein at least one of the error correction circuit, the electronic integrated circuit (comprising amplifier), readout circuit, or the classical computer comprises an integrated circuit, e.g., an application specific integrated circuit or FPGA.

### Method of Operation

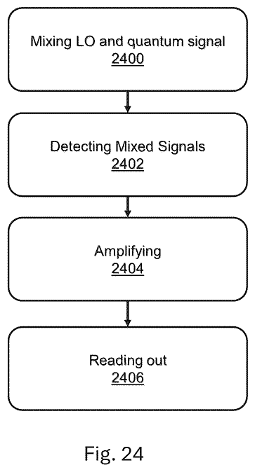

FIG. 24 illustrates a method of receiving a quantum signal comprising mixing the quantum signal with an LO signal (block 2400); detecting the mixed signals (Block 2402); amplifying a difference of the detected signals (block 2404); and optionally reading out the amplified signals (Block 2406). The method can use the receiver of any of the clauses 1-47 above.

### Hardware Environment

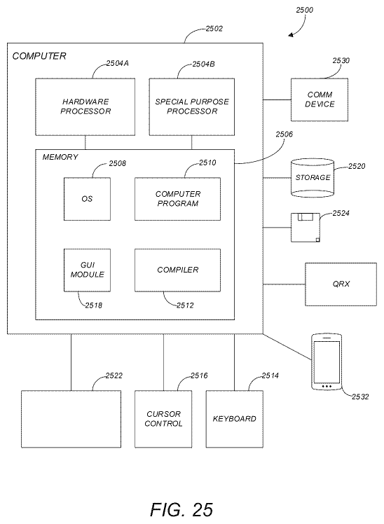

FIG. 25 is an exemplary hardware and software environment 2500 (referred to as a computer-implemented system and/or computer-implemented method) used to implement one or more embodiments of the invention. The hardware and software environment includes a computer 2502 and may include peripherals. Computer 2502 may be a user/client computer, server computer, or may be a database computer. The computer 2502 comprises a hardware processor 2504A and/or a special purpose hardware processor 2504B (hereinafter alternatively collectively referred to as processor 2504) and a memory 2506, such as random access memory (RAM). The computer 2502 may be coupled to, and/or integrated with, other devices, including input/output (I/O) devices such as a keyboard 2514, a cursor control device 2516 (e.g., a mouse, a pointing device, pen and tablet, touch screen, multi-touch device, etc.) and a printer 2528. In one or more embodiments, computer 2502 may be coupled to, or may comprise, a portable or mobile or cellular device or other internet enabled device executing on various platforms and operating systems.

In one embodiment, the computer 2502 operates by the hardware processor 2504A performing instructions defined by the computer program 2510 under control of an operating system 2508 used to perform various classical computing functionalities as described herein. The computer program 2510 and/or the operating system 2508 may be stored in the memory 2506 and may interface with the user and/or other devices to accept input and commands and, based on such input and commands and the instructions defined by the computer program 2510 and operating system 2508, to provide output and results.

Output/results may be presented on the display 2522 or provided to another device for presentation or further processing or action. In one embodiment, the display 2522 comprises a liquid crystal display (LCD) having a plurality of separately addressable liquid crystals. Alternatively, the display 2522 may comprise a light emitting diode (LED) display having clusters of red, green and blue diodes driven together to form full-color pixels. Each liquid crystal or pixel of the display 2522 changes to an opaque or translucent state to form a part of the image on the display in response to the data or information generated by the processor 2504 from the application of the instructions of the computer program 2510 and/or operating system 2508 to the input and commands. The image may be provided through a graphical user interface (GUI) module 2518. Although the GUI module 2518 is depicted as a separate module, the instructions performing the GUI functions can be resident or distributed in the operating system 2508, the computer program 2510, or implemented with special purpose memory and processors.

In one or more embodiments, the display 2522 is integrated with/into the computer 2502 and comprises a multi-touch device having a touch sensing surface (e.g., track pod or touch screen) with the ability to recognize the presence of two or more points of contact with the surface. Examples of multi-touch devices include mobile devices (e.g., IPHONE, NEXUS S, DROID devices, etc.), tablet computers (e.g., IPAD, HP TOUCHPAD, SURFACE Devices, etc.), portable/handheld game/music/video player/console devices (e.g., IPOD TOUCH, MP3 players, NINTENDO SWITCH, PLAYSTATION PORTABLE, etc.), touch tables, and walls (e.g., where an image is projected through acrylic and/or glass, and the image is then backlit with LEDs).

Some or all of the operations performed by the computer 2502 according to the computer program 2510 instructions may be implemented in a special purpose processor 2504B. In this embodiment, some or all of the computer program 2510 instructions may be implemented via firmware instructions stored in a read only memory (ROM), a programmable read only memory (PROM) or flash memory within the special purpose processor 2504B or in memory 2506. The special purpose processor 2504B may also be hardwired through circuit design to perform some or all of the operations to implement the present invention. Further, the special purpose processor 2504B may be a hybrid processor, which includes dedicated circuitry for performing a subset of functions, and other circuits for performing more general functions such as responding to computer program 2510 instructions. In one embodiment, the special purpose processor 2504B is an application specific integrated circuit (ASIC) or field programmable gate array (FPGA) or graphics processing unit (GPU), or an processor adapted or configured for machine learning or artificial intelligence or neural networks.

The computer 2502 may also implement a compiler 2512 that allows an application or computer program 2510 written in a programming language such as C, C++, Assembly, SQL, PYTHON, PROLOG, MATLAB, RUBY, RAILS, HASKELL, or other language to be translated into processor 2504 readable code. Alternatively, the compiler 2512 may be an interpreter that executes instructions/source code directly, translates source code into an intermediate representation that is executed, or that executes stored precompiled code. Such source code may be written in a variety of programming languages such as JAVA, JAVASCRIPT, PERL, BASIC, etc. After completion, the application or computer program 2510 accesses and manipulates data accepted from I/O devices and stored in the memory 2506 of the computer 2502 using the relationships and logic that were generated using the compiler 2512.

The computer 2502 also optionally comprises an external communication device such as a modem, satellite link, Ethernet card, or other device for accepting input from, and providing output to, other computers 2502.

In one embodiment, instructions implementing the operating system 2508, the computer program 2510, and the compiler 2512 are tangibly embodied in a non-transitory computer-readable medium, e.g., data storage device 2520, which could include one or more fixed or removable data storage devices, such as a zip drive, floppy disc drive 2524, hard drive, CD-ROM drive, tape drive, etc. Further, the operating system 2508 and the computer program 2510 are comprised of computer program 2510 instructions which, when accessed, read and executed by the computer 2502, cause the computer 2502 to perform the steps necessary to implement and/or use the present invention or to load the program of instructions into a memory 2506, thus creating a special purpose data structure causing the computer 2502 to operate as a specially programmed computer executing the method steps described herein. Computer program 2510 and/or operating instructions may also be tangibly embodied in memory 2506 and/or data communications devices 2530, thereby making a computer program product or article of manufacture according to the invention. As such, the terms “article of manufacture,” “program storage device,” and “computer program product,” as used herein, are intended to encompass a computer program accessible from any computer readable device or media

Of course, those skilled in the art will recognize that any combination of the above components, or any number of different components, peripherals, and other devices, may be used with the computer 2502.

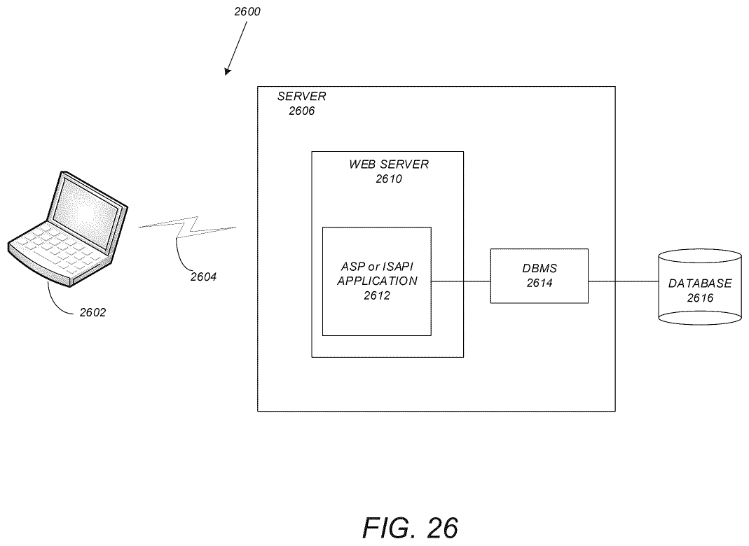

FIG. 26 schematically illustrates a typical distributed/cloud-based computer system 2600 using a network 2604 to connect client computers 2602 to server computers 2606. A typical combination of resources may include a network 2604 comprising the Internet, LANs (local area networks), WANs (wide area networks), SNA (systems network architecture) networks, or the like, clients 2602 that are personal computers or workstations (as set forth in FIG. 25), and servers 2606 that are personal computers, workstations, minicomputers, or mainframes (as set forth in FIG. 25). However, it may be noted that different networks such as a cellular network (e.g., GSM [global system for mobile communications] or otherwise), a satellite based network, or any other type of network may be used to connect clients 2602 and servers 2606 in accordance with embodiments of the invention.

A network 2604 such as the Internet connects clients 2602 to server computers 2606. Network 2604 may utilize ethernet, coaxial cable, wireless communications, radio frequency (RF), etc. to connect and provide the communication between clients 2602 and servers 2606. Further, in a cloud-based computing system, resources (e.g., storage, processors, applications, memory, infrastructure, etc.) in clients 2602 and server computers 2606 may be shared by clients 2602, server computers 2606, and users across one or more networks. Resources may be shared by multiple users and can be dynamically reallocated per demand. In this regard, cloud computing may be referred to as a model for enabling access to a shared pool of configurable computing resources.

Clients 2602 may execute a client application or web browser and communicate with server computers 2606 executing web servers 2610. Such a web browser is typically a program such as MICROSOFT INTERNET EXPLORER/EDGE, MOZILLA FIREFOX, OPERA, APPLE SAFARI, GOOGLE CHROME, etc. Further, the software executing on clients 2602 may be downloaded from server computer 2606 to client computers 2602 and installed as a plug-in or ACTIVEX control of a web browser. Accordingly, clients 2602 may utilize ACTIVEX components/component object model (COM) or distributed COM (DCOM) components to provide a user interface on a display of client 2602. The web server 2610 is typically a program such as MICROSOFT'S INTERNET INFORMATION SERVER.

Web server 2610 may host an Active Server Page (ASP) or Internet Server Application Programming Interface (ISAPI) application 2612, which may be executing scripts. The scripts invoke objects that execute business logic (referred to as business objects). The business objects then manipulate data in database 2616 through a database management system (DBMS) 2614. Alternatively, database 2616 may be part of, or connected directly to, client 2602 instead of communicating/obtaining the information from database 2616 across network 2604. When a developer encapsulates the business functionality into objects, the system may be referred to as a component object model (COM) system. Accordingly, the scripts executing on web server 2610 (and/or application 2612) invoke COM objects that implement the business logic. Further, server 2606 may utilize MICROSOFT'S TRANSACTION SERVER (MTS) to access required data stored in database 2616 via an interface such as ADO (Active Data Objects), OLE DB (Object Linking and Embedding DataBase), or ODBC (Open DataBase Connectivity).

Generally, these components 2600-2616 all comprise logic and/or data that is embodied in/or retrievable from device, medium, signal, or carrier, e.g., a data storage device, a data communications device, a remote computer or device coupled to the computer via a network or via another data communications device, etc. Moreover, this logic and/or data, when read, executed, and/or interpreted, results in the steps necessary to implement and/or use the present invention being performed.

Although the terms “user computer”, “client computer”, and/or “server computer” are referred to herein, it is understood that such computers 2602 and 2606 may be interchangeable and may further include thin client devices with limited or full processing capabilities, portable devices such as cell phones, notebook computers, pocket computers, multi-touch devices, and/or any other devices with suitable processing, communication, and input/output capability. Of course, those skilled in the art will recognize that any combination of the above components, or any number of different components, peripherals, and other devices, may be used with computers 2602 and 2606. Embodiments of the invention are implemented as a software/communication/sensing/computing application on a client 2602 or server computer 2606. Further, as described above, the client 2602 or server computer 2606 may comprise a thin client device or a portable device that has a multi-touch-based display.

### REFERENCES

The following references are incorporated by reference herein.
1. Mandel, L. & Wolf, E. Optical coherence and quantum optics (Cambridge University Press, 1995).
2. Holevo, A. S. Bounds for the quantity of information transmitted by a quantum communication channel. Problemy Peredachi Informatsii 9, 3-11 (1973).
3. Gurses, B. V. & Hajimiri, A. Performance Limits of Sub-Shot-Noise-Limited Balanced Detectors in Frontiers in Optics+Laser Science 2022 (FIO, LS) (Optica Publishing Group, 2022), JW4A. 32.
4. Gurses, V. et al. A compact silicon photonic quantum coherent receiver with deterministic phase control in CLEO 2023 (Optica Publishing Group, 2023), AM4N.4.
5. Gurses, V., Sarkar, D., Davis, S. & Hajimiri, A. An integrated photonic-electronic quantum coherent receiver for sub-shot-noise-limited optical links in Optical Fiber Communication Conference (OFC) 2024 (Optica Publishing Group, 2024), Tu2C.1.
6. Gurses, V., Davis, S. I., Sinclair, N., Spiropulu, M. & Hajimiri, A. Free-space quantum information platform on a chip 2024. arXiv: 2406.09158 [quant-ph].
7. Integrated Optics; and Introduction “Bell Journal (Volume: 48, Issue: 7, September 1969), https://ieeexploreieee.org/document/6769757https://arxiv.org/abs/2406.09158.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A receiver, comprising:
a signal input for receiving a quantum signal;
an LO input for receiving a local oscillator (LO) signal;
one or more couplers for interfering the quantum signal and the LO signal, the couplers comprising a first input connected to the signal input and a second input connected to the LO input; a first output; and a second output, wherein the first output outputs a first interference signal and the second output outputs a second interference signal in response to the interference of the quantum signal and the LO signal;
a pair of photodetectors comprising a first photodetector connected to the first output and a second photodetector connected to the second output; wherein first photodetector and the second photodetector are connected in series and the pair comprises a detector output between the photodetectors and the photodetectors outputting a difference signal between a first output signal (from the first photodetector in response to the first interference signal) and a second output signal (from the second photodetector in response to the second interference signal) such that the output signals cancel each other when they are equal and at least one quadrature component of the quantum signal can be determined from the difference signal.

2. The receiver of claim 1, further comprising a trans-impedance amplifier coupled to the detector output and one or more phase shifters coupled to the couplers.

3. The receiver for claim 2, further comprising an error correction circuit connected to at least one of the phase shifters, wherein the error correction circuit is configured for outputting a feedback signal to the at least one phase shifter controlling a coupling ratio of at least one of the couplers in response to the difference signal, wherein the coupling ratio reduces common-mode noise at the detector output.

4. The receiver of claim 3, wherein the error correction circuit comprises an integrator configured to measure a direct current (DC) component of the difference signal in a presence of the LO signal only and outputting the feedback signal to the at least one phase shifter that cancels or minimizes the DC component and wherein at least one of the phase shifters is configurable to tune one or more of the couplers for 50:50 coupling.

5. The receiver of claim 1, further comprising a Mach Zehnder Interferometer comprising two of the couplers connected in series.

6. The receiver of claim 5, wherein:
the Mach Zehnder Interferometer comprises a push-pull interferometer comprising a first arm outputting to the first coupler output and a second arm outputting the second coupler output;
the first arm is coupled to a first phase shifter; and
the second arm is coupled to a second phase shifter configured to be off when the first phase shifter is on and on when the first phase shifter is off;
wherein the first phase shifter comprises a first diode and the second phase shifter comprises a second diode reverse biased compared to the first diode.

7. The receiver of claim 6, wherein the phase shifters comprise heaters for controlling a refractive index of the arms (and thereby a phase of the signal in each of the arms) through a thermal optical effect; and further comprising a biasing circuit coupled to the photodetectors for independently tuning at least one of a dark current and the response of each of the photodetectors to set a shot noise clearance of the receiver in a predetermined range.

8. The receiver of claim 1, comprising a photonic integrated circuit comprising the first input, the second input, the couplers, and the photodetectors, wherein the couplers comprise coupled waveguides.

9. The receiver of claim 8, further comprising a first substrate comprising the photonic integrated circuit and a second substrate comprising an electronic integrated circuit comprising a trans-impedance amplifier electrically connected to the detector output.

10. The receiver of claim 9, wherein the electronic integrated circuit further comprises:
a voltage amplifier connected to an output of the trans-impedance amplifier; and
a buffer amplifier connected to an output of the voltage amplifier, wherein the buffer amplifier has a buffer output with an impedance for connection to a readout circuit for determining an amplitude and time dependence of the quadrature component from an electrical signal outputted from the buffer amplifier in response to the output signals received from the detector output.

11. The receiver of claim 9, wherein:
the trans-impedance amplifier (TIA) is a field effect transistor (FET)-input operational amplifier (op-amp) with resistive feedback comprising an at least 50 kΩ feedback resistor for >30 dB shot noise clearance; and
the electronic integrated circuit further comprises a 50Ω resistor connected in series with the output of the TIA for impedance matching and having an output for direct connection to a readout circuit for measuring the electrical signal outputted from the TIA in response to the output signals received from the detector output in a sensing application.

12. The receiver of claim 9, wherein:
the photonic integrated circuit further comprises one or more control circuits coupled to at least one of the couplers for controlling a coupling ratio of the couplers, the photodiodes for controlling a dark current and the response of the photodetectors, or an LO power or phase of the LO signal, and
the electronic integrated circuit comprises a gain and output impedance;
such that the receiver:
is shot noise limited and has a shot noise clearance of at least 30 dB, and a Pknee of at most 10 microwatts; or
has 3-dB bandwidth of at least 2 GHz, a shotnoise limited bandwidth of at least 3.5 GHz, a shot noise clearance of at least 10 dB, and a Pknee of at most 500 microwatts.

13. The receiver of claim 9, wherein:
the photonic integrated circuit further comprises one or more control circuits coupled to at least one of the couplers for controlling a coupling ratio of the couplers, the photodetectors for controlling a dark current and response of the photodiodes, or an LO power or phase of the LO signal, and
the electronic integrated circuit comprises a gain and output impedance such that:
a readout circuit coupled to the output of the electronic integrated circuit can decode one of a plurality of spatiotemporal modes of the quantum signal or a variance of the quadrature component from an electrical signal outputted from the electronic integrated circuit in response the output signals outputted at the detector output.

14. The receiver of claim 13, further comprising a phase locking circuit for phase locking the electrical signal to any of the quadrature components of the quantum signal so that an amplitude of the quadrature component can be measured with sub-shot noise level precision or with quantum noise limited precision.

15. The receiver of claim 9, further comprising an array of the receivers wherein an array of the photonic integrated circuits are coupled to the electronic integrated circuit.

16. The receiver of claim 15, further comprising a radio-frequency or microwave circuit after photodetection that can implement arbitrary matrix multiplication for quantum information processing.

17. A computing system comprising the receiver of clause 8, further comprising:
an array of sources that can generate squeezed states or photon number states;
an optical interferometer mesh coupled to the signal input and a co-designed radio-frequency or microwave circuit, connected to the detector output, wherein at least one of the mesh or the RF or microwave circuit can implement arbitrary matrix multiplications to the quantum signals in the photonic or electronic domain while maintaining coherence during optoelectronic downconversion;
single photon detectors connected to some outputs of the optical interferometer mesh for heralding to implement non-Gaussian operations;
a classical computer interfaced with the photonic and electronic quantum circuits that can implement a universal gate set suitable for universal quantum computing.

18. A system comprising the receiver of claim 9, further comprising:
a communication system comprising:
a transmitter for transmitting first electromagnetic radiation comprising the quantum signal encoded with information using one or more degrees of freedom in a phase space representing a quantum state of the quantum signal;
an LO source for transmitting second electromagnetic radiation comprising the LO signal; and
a readout circuit for decoding the information from the degrees of freedom carried by the electrical signal outputted from the electronic integrated circuit; or
a sensor system comprising the receiver of claim 10, further comprising:
a transmitter for transmitting first electromagnetic radiation comprising the quantum signal to a sample, wherein the signal input of the receiver is positioned to receive the first electromagnetic radiation reflected from or transmitted through the sample;
an LO source for transmitting second electromagnetic radiation comprising the LO signal; and
a readout circuit for determining information about the sample from one or more degrees of freedom in a phase space representing a quantum state of the quantum signal and carried in the electrical signal outputted from the electronic integrated circuit; and
wherein the phase space is represented using two orthogonal quadratures and the degrees of freedom include a shape of the phase space or a variance of at least one of the two quadratures characterized by the Heisenberg uncertainty principle ΔxΔp≥ℏ/2 so that the information is encoded in the quantum signal by manipulating single photon statistics of the first electromagnetic radiation and/or preparing and measuring the quadrature component of the quantum signal with a variance below the constant variance associated with a classical coherent state and/or wherein the quantum noise of the quadrature component is below the shot noise limit.

19. The receiver of claim 1, wherein:
the quantum signal is prepared in a squeezed state of light exhibiting reduced noise or variance in one quadrature component and the electrical signal has the noise level that enables measurement of the quadrature component having the reduced noise or variance, or
the quantum signal is prepared in a Fock state or photon number state.

20. A receiver for a quantum signal, comprising:
a mixer for mixing or interfering a local oscillator signal and a quantum signal to form interference signals; and
a pair of photodetectors that can be balanced for outputting a difference signal in response to the interference signals; and
an electronic circuit for amplifying the difference signals and determining a quadrature component of the quantum signal from the difference signals with shot noise limited precision or sub-shot noise limited precision or quantum noise limited precision.
